(19) United States
(12) Patent Application Publication
(10) Pub. No.: US 2017/0283587 A1
(43) Pub. Date: Oct. 5, 2017

(54) CURABLE COMPOSITION, INFRARED CUT FILTER WITH LIGHT-SHIELDING FILM, AND SOLID-STATE IMAGING DEVICE

(71) Applicant: FUJIFILM Corporation, Tokyo (JP)

(72) Inventors: Daisuke HAMADA, Haibara-gun (JP); Satoru MURAYAMA, Haibara-gun (JP); Hideki TAKAKUWA, Haibara-gun (JP); Makoto KUBOTA, Haibara-gun (JP)

(73) Assignee: FUJIFILM Corporation, Tokyo (JP)

(21) Appl. No.: 15/629,909

(22) Filed: Jun. 22, 2017

Related U.S. Application Data
(63) Continuation of application No. PCT/JP2016/051059, filed on Jan. 15, 2016.

(30) Foreign Application Priority Data
Feb. 9, 2015 (JP) 2015-023656
Aug. 31, 2015 (JP) 2015-171579

(51) Int. Cl. C08K 5/544; H01L 27/146; G02B 5/20; C08K 3/22; C08J 5/18

(52) U.S. Cl. CPC C08K 5/544; C08K 3/22; C08J 5/18; G02B 5/208; H01L 27/14621; C08K 2003/2237; C08J 2335/02

(57) ABSTRACT

The present invention provides a curable composition which is suitably used for the production of a light-shielding film which has excellent light-shielding properties, exhibits low reflectivity, has excellent pattern linearity, and is not susceptible to chipping; an infrared cut filter with a light-shielding film; and a solid-state imaging device. The curable composition according to the present invention includes a curable compound which has at least one selected from the group consisting of a fluorine atom, a silicon atom, a linear alkyl group having 8 or more carbon atoms, and a branched alkyl group having 3 or more carbon atoms, and a curable functional group; a silane coupling agent; and a black pigment.

### CROSS-REFERENCE TO RELATED APPLICATIONS

This application is a Continuation of PCT International Application No. PCT/JP2016/051059 filed on Jan. 15, 2016, which claims priority under 35 U.S.C. §119(a) to Japanese Patent Application No. 2015-023656 filed on Feb. 9, 2015 and Japanese Patent Application No. 2015-171579 filed on Aug. 31, 2015. Each of the above applications is hereby expressly incorporated by reference, in its entirety, into the present application.

### BACKGROUND OF THE INVENTION

### 1. Field of the Invention

The present invention relates to a curable composition, an infrared cut filter with a light-shielding film, and a solid-state imaging device.

### 2. Description of the Related Art

A solid-state imaging device includes a taking lens, a solid-state imaging element such as a charge coupled device (CCD) and a complementary metal oxide film semiconductor (CMOS), disposed behind the taking lens, and a circuit board on which the solid-state imaging element is mounted. This solid-state imaging device is loaded in a digital camera, a mobile phone with a camera, a smartphone, or the like.

In the solid-state imaging device, a noise derived from the reflection of visible light may be generated in some cases. In this regard, in JP2012-169556A, suppression of noise generation is achieved by providing a predetermined light-shielding film in a solid-state imaging device. As a composition for forming a light-shielding film, a light-shielding composition including a black pigment such as titanium black is used.

### SUMMARY OF THE INVENTION

On the other hand, the light-shielding film has recently been required to satisfy various demands.

For example, as the solid-state imaging device becomes smaller, thinner, and more sensitive, the light-shielding film is required to have even further low reflectivity.

Furthermore, the light-shielding film may be formed in the pattern shape in many cases, and thus, further reduction in a variation in the width of the linear pattern to be formed is required. In the present specification, a property of forming the pattern in the linear shape (line shape) is referred to as “linearity of the pattern”, and in a case where the linearity of the pattern is excellent, it is intended that the variation in the width of the linear pattern to be formed is small.

In addition, the light-shielding film (in particular, the light-shielding film formed in the pattern shape) is required to be not susceptible to chipping in terms of handling properties.

That is, the light-shielding film is required to have excellent light-shielding properties, as well as to exhibit low reflectivity, have excellent pattern linearity, and be not susceptible to chipping.

The present inventors have produced a light-shielding film using a black radiation-sensitive composition A specifically disclosed in JP2012-169556A, have examined the characteristics thereof, and thus, have found that a light-shielding film that satisfies all the characteristics is not obtained and needs a further improvement.

In view of the circumstances, the present invention has an object to provide a curable composition which is suitably used for production of a light-shielding film having excellent light-shielding properties, exhibiting low reflectivity, having excellent pattern linearity, and being not susceptible to chipping.

In addition, the present invention has another object to provide an infrared cut filter with a light-shielding film and a solid-state imaging device, each having a light-shielding film formed of the curable composition.

The present inventors have conducted extensive studies in order to achieve the objects, and thus, have found that the objects can be achieved by using a curable composition including a predetermined curable compound and a silane coupling agent, thereby completing the present invention.

That is, the present inventors have found that the objects can be achieved by the following configuration.

(1) A curable composition comprising: a curable compound having at least one selected from the group consisting of a fluorine atom, a silicon atom, a linear alkyl group having 8 or more carbon atoms (the number of carbon atoms of 8), and a branched alkyl group having 3 or more carbon atoms, and a curable functional group;

a silane coupling agent; and

a black pigment.

(2) The curable composition as described in (1), in which the silane coupling agent is a silane coupling agent with a molecular weight of 270 or more, having at least one curable functional group selected from the group consisting of a (meth)acryloyloxy group, an epoxy group, and an oxetanyl group.

(3) The curable composition as described in (1) or (2), in which the curable compound has at least one curable functional group selected from the group consisting of a (meth)acryloyloxy group, an epoxy group, an oxetanyl group, an isocyanate group, a hydroxyl group, an amino group, a carboxyl group (carboxylic acid group), a thiol group, an alkoxysilyl group, a methylol group, a vinyl group, a (meth)acrylamide group, a styryl group, and a maleimide group.

(4) The curable composition as described in any one of (1) to (3), in which the curable compound has at least one curable functional group selected from the group consisting of a (meth)acryloyloxy group, an epoxy group, and an oxetanyl group.

(5) The curable composition as described in any one of (1) to (4), further comprising: a polymerizable compound; a polymerization initiator; an alkali-soluble resin; and a solvent.

(6) The curable composition as described in any one of (1) to (5), in which the curable compound alone is capable of forming a film with a refractive index of 1.1 to 1.5 at a wavelength of 550 nm.

(7) The curable composition as described in any one of (1) to (6), in which the content of the silane coupling agent is 0.1% to 10% by mass with respect to the total solid content in the curable composition.

(8) The curable composition as described in any one of (1) to (7), in which the content of the curable compound is 0.1% to 20% by mass with respect to the total solid content in the curable composition.

(9) The curable composition as described in any one of (1) to (8), in which the content of the black pigment is 20% to 80% by mass with respect to the total solid content in the curable composition.

(10) The curable composition as described in any one of (1) to (9), in which the black pigment is titanium black.

(11) An infrared cut filter with a light-shielding film, comprising:

an infrared cut filter; and

a light-shielding film formed of the curable composition as described in any one of (1) to (10), disposed on at least a part of the surface of the infrared cut filter.

(12) A solid-state imaging device comprising the infrared cut filter as described in (11).

According to the present invention, it is possible to provide a curable composition which is suitably used for production of a light-shielding film having excellent light-shielding properties, exhibiting low reflectivity, having excellent pattern linearity, and being not susceptible to chipping.

In addition, according to the present invention, it is also possible to provide an infrared cut filter with a light-shielding film and a solid-state imaging device, each having a light-shielding film formed of the curable composition.

### BRIEF DESCRIPTION OF THE DRAWINGS

FIG. 1 shows a cross-sectional view of a suitable embodiment of a light-shielding film of the present invention.

FIG. 2 is a perspective view illustrating a solid-state imaging device of a first embodiment.

FIG. 3 is an exploded perspective view illustrating the solid-state imaging device of the first embodiment.

FIG. 4 is a cross-sectional view illustrating the solid-state imaging device of the first embodiment.

FIG. 5 is a cross-sectional view illustrating a solid-state imaging device of a second embodiment.

FIG. 6 is a cross-sectional view illustrating a solid-state imaging device of a third embodiment.

FIG. 7 is a cross-sectional view illustrating a solid-state imaging device of a fourth embodiment.

### DESCRIPTION OF THE PREFERRED EMBODIMENTS

Hereinafter, suitable aspects of the curable composition (hereinafter also simply referred to as the “composition” or “the composition of the present invention”), an infrared cut filter with a light-shielding film, and a solid-state imaging device of the present invention will be described in detail.

Incidentally, in citations for a group (atomic group) in the present specification, when the group is denoted without specifying whether it is substituted or unsubstituted, the group includes both a group having no substituent and a group having a substituent. For example, an “alkyl group” includes not only an alkyl group having no substituent (unsubstituted alkyl group), but also an alkyl group having a substituent (substituted alkyl group).

Furthermore, “radiation” in the present specification encompasses visible light, ultraviolet rays, far ultraviolet rays, electron beams, X-rays, and the like.

The explanation of constituents which will be described hereinafter may be made based on typical embodiments of the present invention in some cases, but the present invention is not limited to such embodiments. Further, in the present specification, “(a value) to (a value)” is used to mean a range including the numeric values described before and after “to” as a lower limit value and an upper limit value, respectively.

In the present specification, “(meth)acrylate” represents acrylate and methacrylate, “(meth)acryl” represents acryl and methacryl, “(meth)acryloyl” represents acryloyl and methacryloyl, and “(meth)acrylamide” represents acrylamide and methacrylamide. In addition, in the present specification, a “monomeric material” and a “monomer” have the same definition. The monomer in the present invention refers to a compound which is distinguished from an oligomer or a polymer and has a weight-average molecular weight of 2,000 or less. In the present specification, a polymerizable compound refers to a compound having a polymerizable group, and may be either a monomer or a polymer. The polymerizable group refers to a group involved in a polymerization reaction.

The present invention may be characterized, for example, in that it uses a curable compound having a predetermined structure and a silane coupling agent. Hereinafter, presumptions on the reasons why the effects of the present invention are obtained will be described.

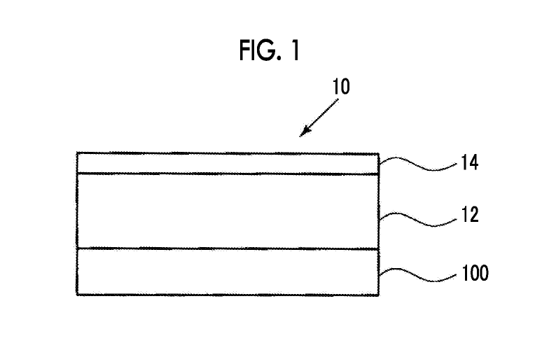

First, the curable compound includes at least one selected from the group consisting of a fluorine atom, a silicon atom, a linear alkyl group having 8 or more carbon atoms, and a branched alkyl group having 3 or more carbon atoms, and these atoms or functional groups exhibit low surface free energy. Therefore, for example, in a coating film formed by applying the curable composition onto a substrate, the curable compound is likely to be present at a high concentration near the surface of the coating film on the side opposite to the substrate. As a result, as shown in FIG. 1, a light-shielding, film 10 on a substrate 100 obtained by curing a coating film has a bilayer structure with a black layer (under layer) 12 including a black pigment and a coating layer (upper layer) 14 formed of the curable compound. When such a bilayer structure is formed, the light reflected on the surface of the coating layer and the light reflected on the interface between the coating layer and the black layer are canceled by interference, thus realizing low reflectivity.

In addition, due to the presence of the curable compound-derived curable functional group and the silane coupling agent, the undercut is suppressed, the chipping of the light-shielding film is suppressed, and the linearity of the pattern is also excellent at the time of manufacturing a light-shielding film in the pattern shape.

Hereinafter, first of all, the compositional ratio of the curable composition of the present invention (composition for forming a light-shielding film) will be described in detail.

The curable composition includes at least a curable compound having at least one selected from the group consisting of a fluorine atom, a silicon atom, a linear alkyl group having 8 or more carbon atoms, and a branched alkyl group having 3 or more carbon atoms, and a curable functional group; a silane coupling agent; and a black pigment. In addition, the curable compound is a different compound from the silane coupling agent.

Hereinafter, the respective components will be described in detail.

<Curable Compound>

The curable compound has at least one selected from the group consisting of a fluorine atom, a silicon atom, a linear alkyl group having 8 or more carbon atoms, and a branched alkyl group having 3 or more carbon atoms, and a curable functional group. Further, from the viewpoints of achieving at least one of lowering the reflectivity of the light-shielding film, improving the pattern linearity of the light-shielding film, or making the light-shielding film further not susceptible to chipping (hereinafter also simply referred to “the effects of the present invention are more excellent”), it is preferable that the curable compound has a fluorine atom and/or a branched alkyl group having 6 or more carbon atoms.

Furthermore, the curable compound may be a monomer, a multimer, or a polymer. In a case where the curable compound is a polymer, it is preferably a (meth)acrylate polymer, and more preferably a (meth)acrylate polymer having a fluorine atom.

Moreover, as one of suitable aspects of the curable compound, a compound which does not have a benzene ring structure may be mentioned, and a compound which has a fluorine atom and does not have a benzene ring structure is preferable.

In addition, the silane coupling agent which will be described later is not included in the curable compound.

In a case where the curable compound includes a fluorine atom, the curable compound preferably has at least one selected from the group consisting of an alkylene group substituted with a fluorine atom, an alkyl group substituted with a fluorine atom, and an aryl group substituted with a fluorine atom.

The alkylene group substituted with a fluorine atom is preferably a linear, branched, or cyclic alkylene group in which at least one hydrogen atom is substituted with a fluorine atom.

The alkyl group substituted with a fluorine atom is preferably a linear, branched, or cyclic alkyl group in which at least one hydrogen atom is substituted with a fluorine atom.

The alkylene group substituted with a fluorine atom and an alkyl group substituted with a fluorine atom preferably has 1 to 20 carbon atoms, more preferably has 1 to 10 carbon atoms, and still more preferably has 1 to 5 carbon atoms.

With regard to the aryl group substituted with a fluorine atom, it is preferable that the aryl group is directly substituted with a fluorine atom or substituted with a trifluoromethyl group.

The alkylene group substituted with a fluorine atom, an alkyl group substituted with a fluorine atom, and an aryl group substituted with a fluorine atom may further have another substituent, in addition to the fluorine atom.

With regard to the alkyl group substituted with a fluorine atom and the aryl group substituted with a fluorine atom, reference can be made to paragraphs 0266 to 0272 of JP2011-100089A, the contents of which are incorporated herein by reference.

Among those, from the viewpoint that the effects of the present invention are more excellent, it is preferable that the curable compound includes a group X having an alkylene group substituted with a fluorine atom and an oxygen atom linked to each other (group (repeating unit) represented by Formula (X)), and it is more preferable that the curable compound contains a perfluoroalkylene ether group.

-(L_{A}-O)— Formula (X)

L_{A} represents an alkylene group substituted with a fluorine atom. Further, the number of carbon atoms in the alkylene group is preferably 1 to 20, more preferably 1 to 10, and still more preferably 1 to 5. Further, an oxygen atom may also be contained in the alkylene group substituted with a fluorine atom.

Furthermore, the alkylene group substituted with a fluorine atom may be linear or branched.

The perfluoroalkylene ether group is intended to mean that L_{A} is a perfluoroalkylene group. The perfluoroalkylene group is intended to mean the group in which all the hydrogen atoms in the alkylene group are substituted with a fluorine atom.

The groups (repeating units) represented by Formula (X) may be linked in repetition, and the number of the repeating units is not particularly limited, but is preferably 1 to 50, and more preferably 1 to 20, from the viewpoint that the effects of the present invention are more excellent.

That is, the group is preferably a group represented by Formula (X-1).

-(L_{A}-O)ᵣ— Formula (X-1)

In Formula (X-1), L_{A} is as described above, r represents the number of the repeating units, and a suitable range thereof is as described above.

Furthermore, L_{A}'s in a plurality of -(L_{A}-O)—'s may be the same as or different from each other.

In a case where the curable compound contains a silicon atom, it is preferably an alkylsilyl group, an arylsilyl group, or the following partial structure (S) (* represents a binding site to another atom).

Partial Structure (S)

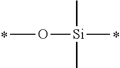

The total number of carbon atoms of the alkyl chain included in the alkylsilyl group is preferably 1 to 20, more preferably 1 to 10, and still more preferably 1 to 6. For example, an alkylsilyl group and a trialkylsilyl group are preferable.

Examples of the aryl group in the arylsilyl group include a phenyl group.

In a case where the curable compound includes the partial structure (S), it may form a cyclic structure including the partial structure (S). As the partial structure (S) which is preferably adopted in the present invention, —Si(R)₂—O—Si(R)₂—(R is an alkyl group having 1 to 3 carbon atoms), and an alkoxysilyl group are preferable. With regard to the structure including the partial structure (S), reference can be made to, for example, paragraphs 0277 to 0279 of JP2011-100089A, the contents of which are incorporated herein by reference.

In a case where the curable compound contains a linear alkyl group having 8 or more carbon atoms, the number of carbon atoms thereof is preferably 8 to 30, and more preferably 12 to 20.

In a case where the curable compound contains a branched alkyl group having 3 or more carbon atoms, the number of carbon atoms of the branched alkyl group is preferably 3 to 20, more preferably 5 to 15, and still more preferably 6 to 15. The branched alkyl group having 3 or more carbon atoms preferably has —CH(CH₃)₂ or —C(CH₃)₃ at the terminal.

As long as the curable compound has one or more of at least one selected from the group consisting of a fluorine atom, a silicon atom, a linear alkyl group having 8 or more carbon atoms, and a branched alkyl group having 3 or more carbon atoms, it may also have two or more atoms or groups. Further, the curable compound may also have a combination of at least one of selected from the group consisting of a fluorine atom, a silicon atom, a linear alkyl group having 8 or more carbon atoms, and a branched alkyl group having 3 or more carbon atoms.

The curable compound may have one or more curable functional groups, and may also have two or more curable functional groups. The curable functional groups may be used singly or in combination of two or more kinds thereof. The curable functional group may be a thermosetting functional group or a photocurable functional group.

The curable functional group is preferably at least one selected from the group consisting of a (meth)acryloyloxy group, an epoxy group, an oxetanyl group, an isocyanate group, a hydroxyl group, an amino group, a carboxyl group, a thiol group, an alkoxysilyl group, a methylol group, a vinyl group, a (meth)acrylamide group, a styryl group, and a maleimide group, and more preferably at least one selected from the group consisting of a (meth)acryloyloxy group, an epoxy group, and an oxetanyl group.

In addition, in a case where an ethylenically unsaturated group is contained as the curable functional group, the amount of the ethylenically unsaturated group in the curable compound is preferably 0.1 to 10.0 mol/g and more preferably 1.0 to 5.0 mol/g.

In a case where the curable compound is a monomer, the number of at least one group selected from the group consisting of a fluorine atom, a silicon atom, a linear alkyl group having 8 or more carbon atoms, and a branched alkyl group having 3 or more carbon atoms in one molecule is preferably 1 to 20, and more preferably 3 to 15.

Furthermore, the number of the curable functional groups in one molecule is not particularly limited, but is preferably 2 or more, and more preferably 4 or more, from the viewpoint that the effects of the present invention are more excellent. The upper limit thereof is not particularly limited, but is 10 or less in many cases, and 6 or less in more cases.

In a case where the curable compound is a polymer, the curable compound preferably has at least one of a repeating unit represented by the following Formula (B1) a repeating unit represented by the following Formula (B2), and a repeating unit represented by Formula (B3).

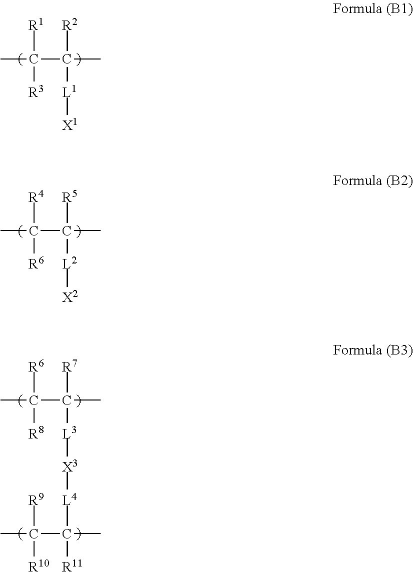

In Formulae (B1) to (B3), R¹ to R¹¹ each independently represent a hydrogen atom, an alkyl group, or a halogen atom. L¹ to L⁴ each independently represent a single bond or a divalent linking group. X¹ represents a (meth)acryloyloxy group, an epoxy group, or an oxetanyl group, X² represents an alkyl group substituted with a fluorine atom, an aryl group substituted with a fluorine atom, an alkylsilyl group, an arylsilyl group, a group including the partial structure (S), a linear alkyl group having 8 or more carbon atoms, or a branched alkyl group having 3 or more carbon atoms, and X³ represents the repeating unit represented by Formula (X-1).

In Formulae (B1) to (B3), R¹ to R¹¹ are each independently preferably a hydrogen atom or an alkyl group. In a case where R¹ to R¹¹ each represent an alkyl group, an alkyl group having 1 to 3 carbon atoms is preferable. In a case where R¹ to R¹¹ each represent a halogen atom, a fluorine atom is preferable.

In Formulae (B1) to (B3), in a case where L¹ to L⁴ each represent a divalent linking group, examples of the divalent linking group include an alkylene group which may be substituted with a halogen atom, an arylene group which may be substituted with a halogen atom, —NR¹²—, —CONR¹²—, —CO—, —CO₂—, SO₂NR¹²—, —O—, —S—, —SO₂—, and a combination thereof. Among those, at least one selected from the group consisting of an alkylene group having 2 to 10 carbon atoms, which may be substituted with a halogen atom, and an arylene group having 6 to 12 carbon atoms, which may be substituted with a halogen atom, or a combination of these groups with at least one group selected from the group consisting of —NR¹²—, —CONR¹²—, —CO—, —CO₂—, SO₂NR¹²—, —O—, —S—, and SO₂— is preferable, and an alkylene group having 2 to 10 carbon atoms, which may be substituted with a halogen atom, —CO₂—, —O—, —CO—, —CONR¹²—, or a group formed by a combination of these groups is more preferable. Here, R¹² represents a hydrogen atom or a methyl group.

Specific examples of the repeating unit represented by Formula (B1) include the following repeating units, but the present invention is not limited thereto.

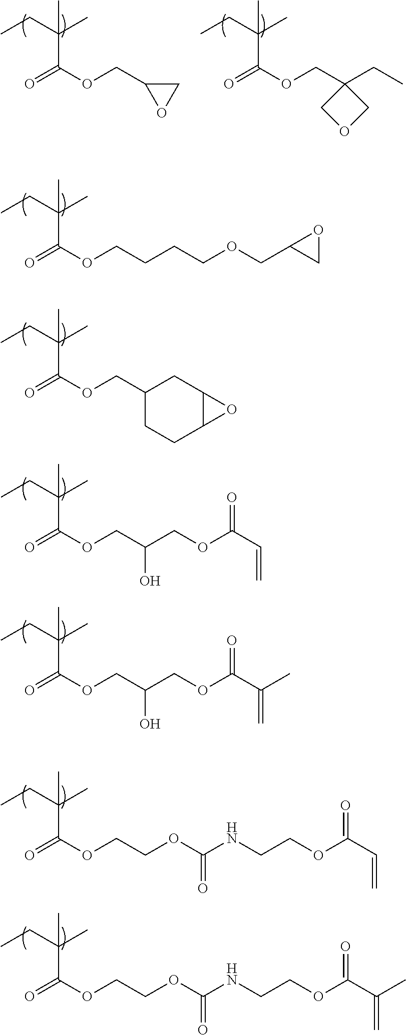

Furthermore, specific examples of the repeating unit represented by Formula (B2) include the following repeating units, but the present invention is not limited thereto. In the specific examples, X¹ represents a hydrogen atom, —CH₃, —F, or —CF₃, and is preferably a hydrogen atom or a methyl group. Me represents a methyl group.

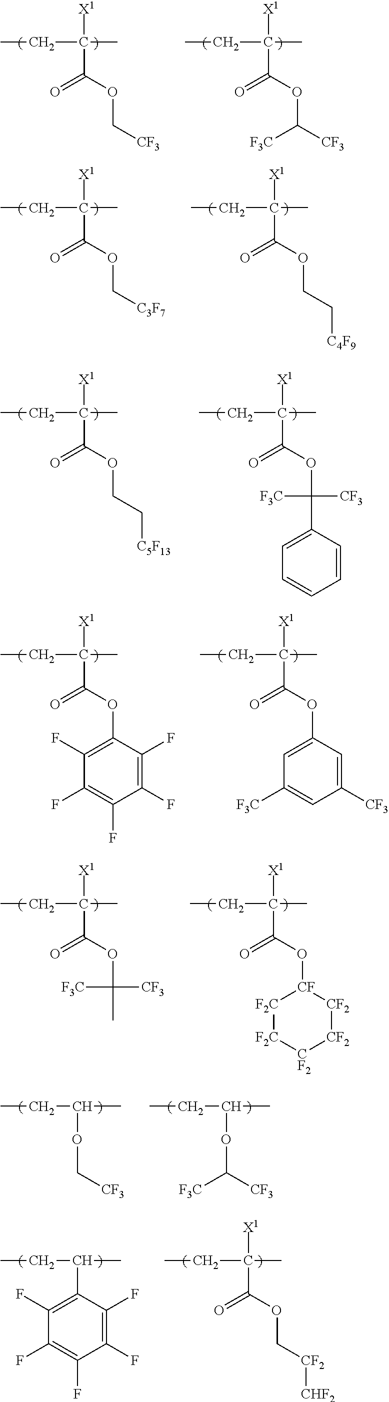

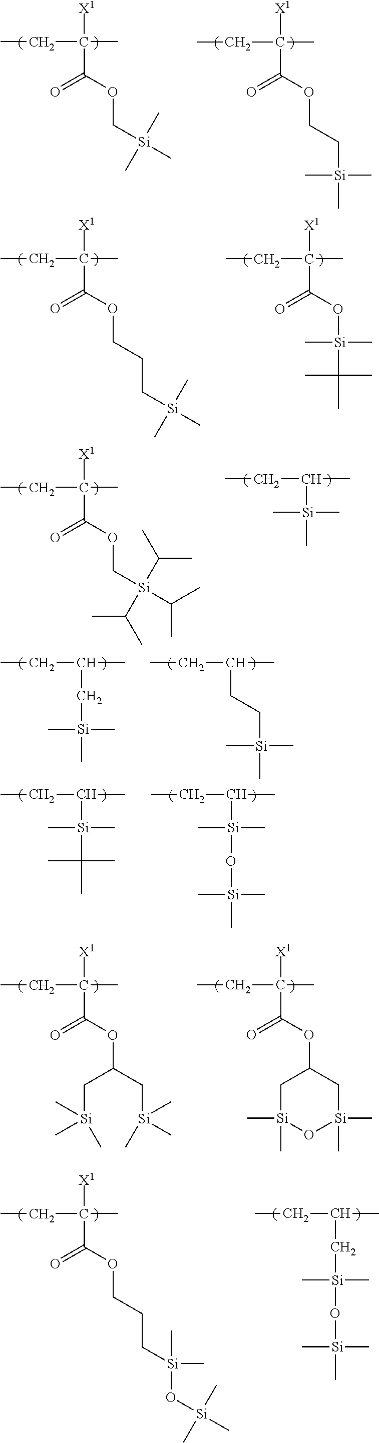

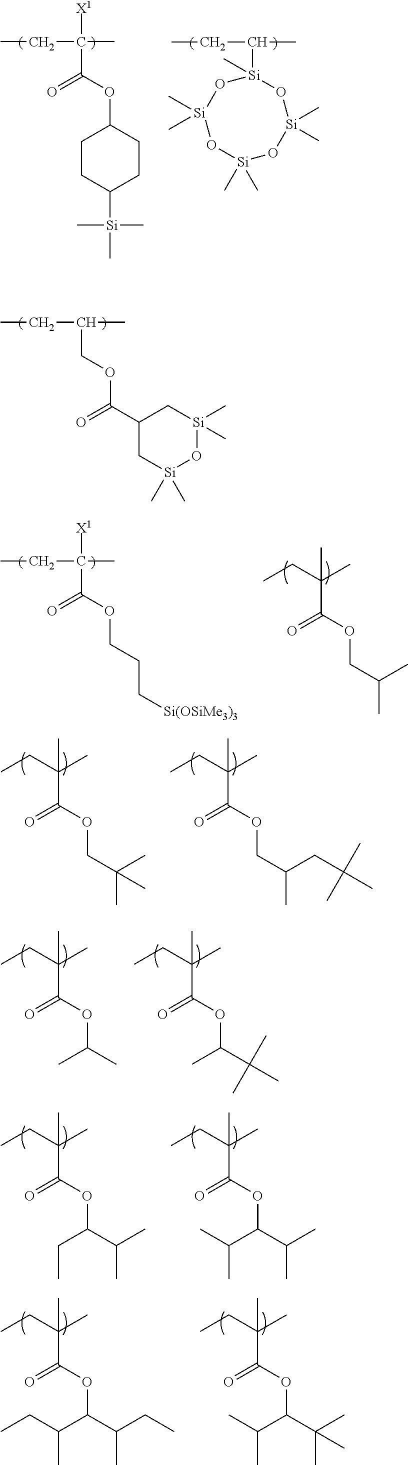

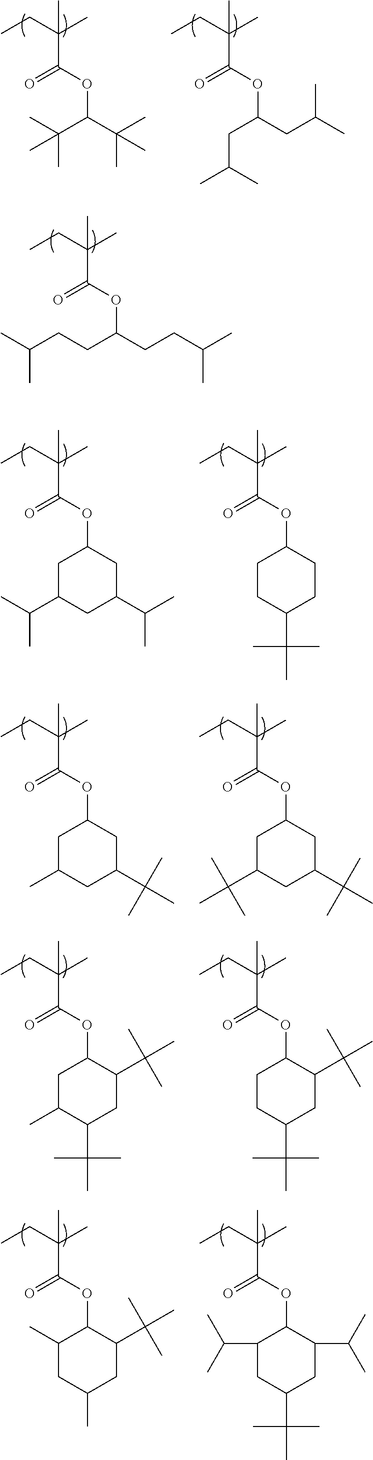

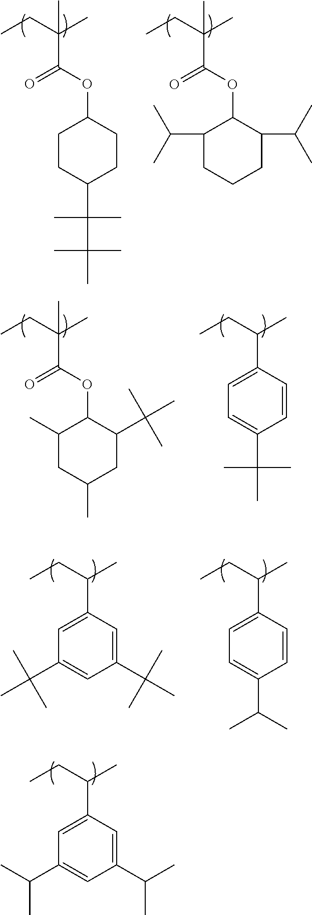

Furthermore, specific examples of the repeating unit represented by Formula (B3) included the following repeating units, but the present invention is not limited thereto.

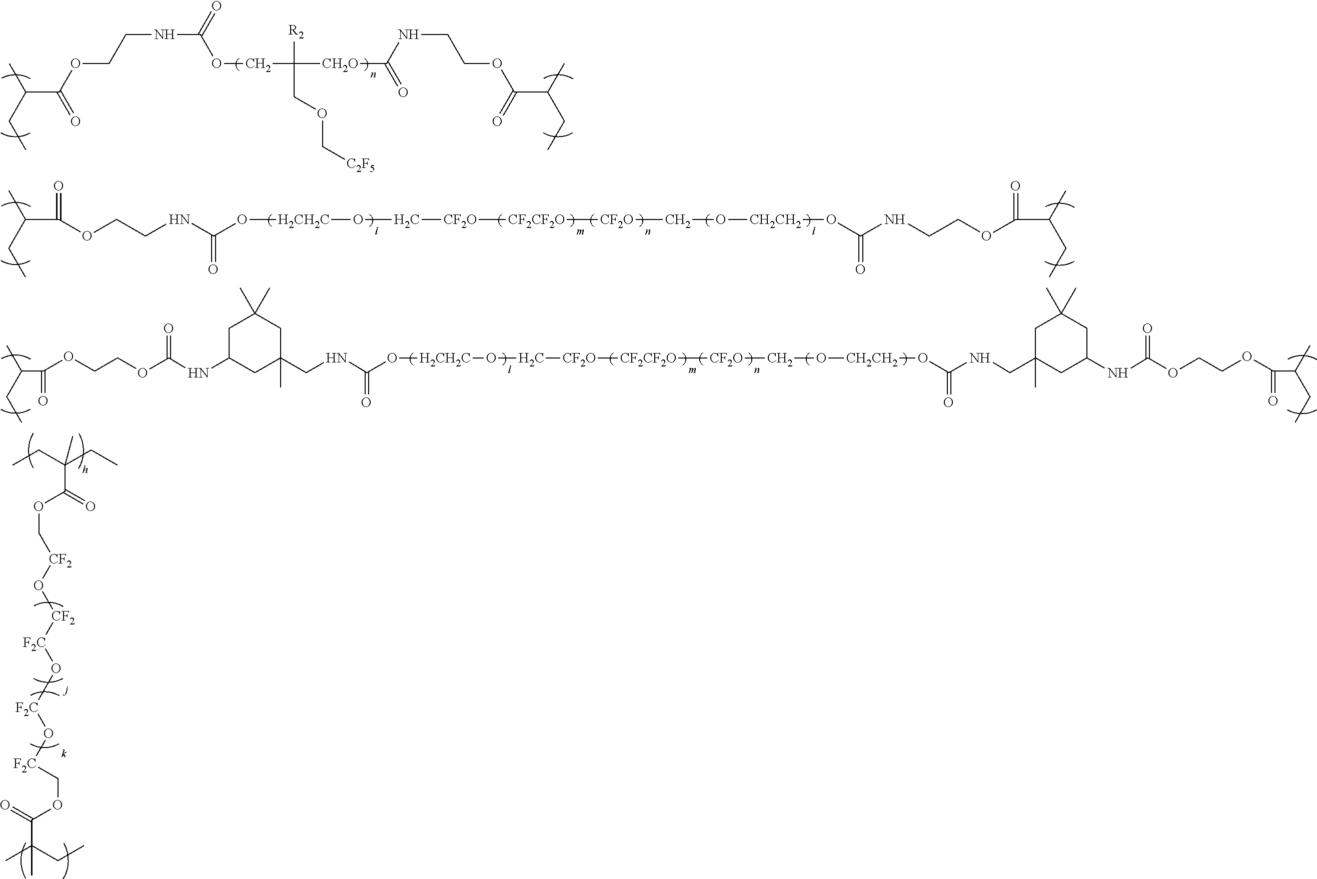

The content of the repeating unit represented by Formula (B1) is preferably 30% to 95% by mole, and more preferably 45% to 90% by mole, with respect to all the repeating units in the curable compound. That is, the content of the repeating unit represented by Formula (B1) is preferably 30% by mole or more, and more preferably 45% by mole or more, with respect to all the repeating units in the curable compound.

The total content of the repeating unit represented by Formula (B2) and the repeating unit represented by Formula (B3) is preferably 5% to 70% by mole, and more preferably 10% to 60% by mole, with respect to all the repeating units in the curable compound. That is, the total content of the repeating unit represented by Formula (B2) and the repeating unit represented by Formula (B3) is preferably 5% by mole or more, and more preferably 10% by mole or more, with respect to all the repeating units in the curable compound.

In addition, in a case where the repeating unit represented by Formula (B2) is not included and the repeating unit represented by Formula (B3) is included, the content of the repeating unit represented by Formula (B2) is 0% by mole, and the content of the repeating unit represented by Formula (B3) is preferably within the above range.

Moreover, the curable compound may have repeating units other than the repeating units represented by Formulae (B1) to (B3). The content of such other repeating units is preferably 10% by mole or less, and more preferably 1% by mole or less, with respect to all the repeating units in the curable compound.

In a case where the curable compound is a polymer, the weight-average molecular weight (Mw: polystyrene-equivalent) thereof is preferably 5,000 to 100,000, and more preferably 7,000 to 50,000. In a case where the curable compound is a polymer, the weight-average molecular weight thereof is preferably 5,000 or more, and more preferably 7,000 or more.

Furthermore, in a case where the curable compound is a polymer, the dispersity (weight-average molecular weight/number-average molecular weight) thereof is preferably 1.80 to 3.00, and more preferably 2.00 to 2.90. In a case where the curable compound is a polymer, the dispersity thereof is preferably 1.80 or more, and more preferably 2.00 or more.

The gel permeation chromatography (GPC) method uses HLC-8020GPC (manufactured by Tosoh Corporation), and is based on a method using TSKgel Super HZM-H, TSKgel Super HZ4000, or TSKgel Super HZ2000 (manufactured by Tosoh Corporation, 4.6 mm ID×15 cm) as a column and tetrahydrofuran (THF) as an eluent.

As one of suitable aspects of the curable compound, a curable compound having repeating units similar to the repeating unit A represented by Structural Formula (I) and the repeating unit B represented by Structural Formula (II), described in claim 10 of JP2010-164965A, may be mentioned.

More specifically, aspects having a repeating unit represented by the following Formula (A1) and a repeating unit represented by the following Formula (A2) may be mentioned.

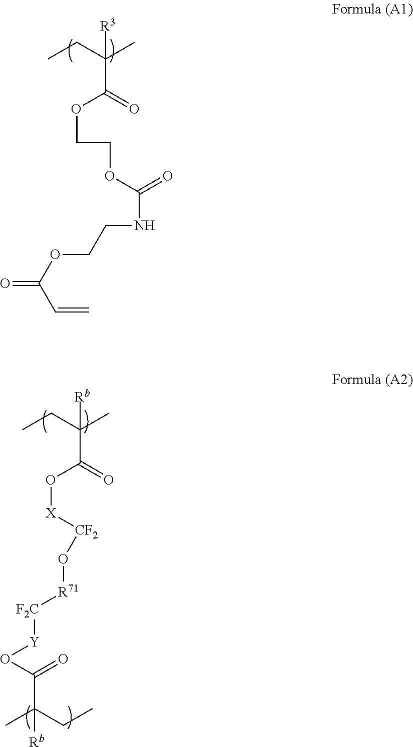

In Formula (A1), R^{a} represents a hydrogen atom or a methyl group.

In Formula (A2), R^{b}'s each independently represent a hydrogen atom or a methyl group.

In Formula (A2), R⁷¹ represents a partial structure having one or more of repeating units a to e represented by the following Structural Formulae (71a) to (71e).

X and Y each independently represent any one of the following Structural Formulae (K1) to (K3). Further, w represents any one integer of 1 to 20.

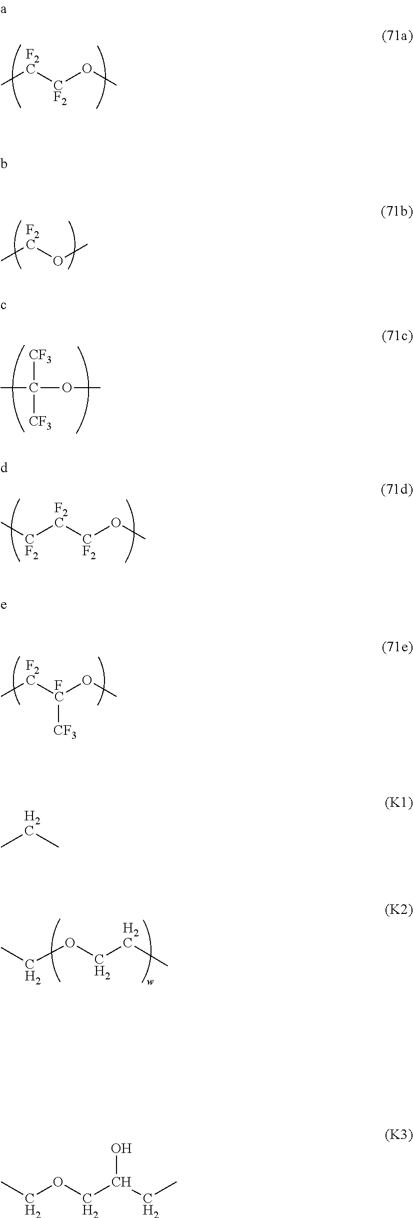

Examples of the curable compound having the repeating unit represented by Formula (A1) and the repeating unit represented by Formula (A2) include RS-718-K and RS-72-K.

In addition, with regard to commercially available products of the curable compound, examples of the curable compound having a fluorine atom include MEGAFACE RS-72-K, MEGAFACE RS-75, MEGAFACE RS-76-E, MEGAFACE RS-76-NS, and MEGAFACE RS-77, all manufactured by DIC Corporation; examples of the curable compound having a silicon atom include BYK-UV 3500, BYK-UV 3530, and BYK-UV 3570, all manufactured by BYK; and TEGO Rad 2010, TEGO Rad 2011, TEGO Rad 2100, TEGO Rad 2200N, TEGO Rad 2250, TEGO Rad 2300, TEGO Rad 2500, TEGO Rad 2600, TEGO Rad 2650, and TEGO Rad 2700, all manufactured by Evonik Industries AG.

Among those, from the viewpoint of lowering the reflectivity, the curable compound having a fluorine atom is preferable.

The curable compound is preferably a curable compound which is capable of forming a film with a refractive index of 1.1 to 1.5 at a wavelength of 550 nm, formed of the curable compound alone. That is, the refractive index at a wavelength of 550 nm formed of the curable compound alone is preferably 1.1 to 1.5.

A suitable range of the refractive index is preferably 1.2 to 1.5, and more preferably 1.3 to 1.5, from the viewpoint of the low reflectivity of the light-shielding film.

The content of the curable compound in the composition is preferably 0.1% to 20% by mass, more preferably 0.5% to 15% by mass, still more preferably 1.0% to 10% by mass, particularly preferably 2% to 10% by mass, and most preferably 4% to 10% by mass, with respect to the total solid content of the composition.

The composition may include one kind or two or more kinds of the curable compound. In a case where the composition includes two or more kinds of the curable compounds, the total amount thereof may be any one within the above range.

<Silane Coupling Agent>

The silane coupling agent is a compound having a hydrolyzable group and other functional groups in the molecule. Further, the hydrolyzable group such as an alkoxy group is bonded to a silicon atom.

The hydrolyzable group refers to a substituent that can be directly linked to a silicon atom to generate a siloxane bond by a hydrolysis reaction and/or a condensation reaction. Examples of the hydrolyzable group include a halogen atom, an alkoxy group, an acyloxy group, and an alkenyloxy group. In a case where the hydrolyzable group has a carbon atom, the number of carbon atoms thereof is preferably 6 or less, and more preferably 4 or less. In particular, an alkoxy group having 4 or less carbon atoms or an alkenyloxy group having 4 or less carbon atoms is preferable. In addition, an alkoxy group having 2 or less carbon atoms or an alkenyloxy group having 2 or less carbon atoms is preferable.

Moreover, in order to improve the adhesiveness between a substrate and a light-shielding film, it is preferable that the silane coupling agent does not include any of a fluorine atom and a silicon atom (provided that a silicon atom to which the hydrolyzable group is bonded is excluded), and it is also preferable that the silane coupling agent does not include any of a fluorine atom, a silicon atom (provided that a silicon atom to which the hydrolyzable group is bonded is excluded), an alkylene group substituted with a silicon atom, a linear alkyl group having 8 or more carbon atoms, and a branched alkyl group having 3 or more carbon atoms.

The silane coupling agent preferably has a group represented by the following Formula (Z). * represents a binding position.

*—Si—(R_{Z1})₃ Formula (Z)

In Formula (Z), R_{Z1} represents a hydrolyzable group, and the definition thereof is as described above.

The silane coupling agent may have a curable functional group exemplified as the curable compound, and preferably has at least one curable functional group selected from the group consisting of a (meth)acryloyloxy group, an epoxy group, and an oxetanyl group from the viewpoint that the effects of the present invention are more excellent. The curable functional group may be directly bonded to a silicon atom or may be bonded to a silicon atom via a linking group.

In addition, suitable aspects of the curable functional group contained in the silane coupling agent may also include a radically polymerizable group.

The molecular weight of the silane coupling agent is not particularly limited, and from the viewpoint of handling properties, it is 100 to 1,000 in many cases, and from the viewpoint that the effects of the present invention are more excellent, is preferably 270 or more, and more preferably 270 to 1,000.

As one suitable aspect of the silane coupling agent, a silane coupling agent X represented by Formula (W) may be mentioned.

R_{Z2}-Lz-Si—(R_{Z1})₃ Formula (W)

R_{z1} represents a hydrolyzable group, and the definition thereof is as described above.

R_{z2} represents a curable functional group, and a definition and suitable range thereof are each as described above.

Lz represents a single bond or a divalent linking group. The divalent linking group has the same definitions as the divalent linking group represented by L¹ to L⁴ in Formulae (B1) to (B3).

Examples of the silane coupling agent X include N-β-aminoethyl-γ-aminopropyl-methyldimethoxysilane (trade name: KBM-602, manufactured by Shin-Etsu Chemical Co., Ltd.), N-β-aminoethyl-γ-aminopropyl-trimethoxysilane (trade name: KBM-603, manufactured by Shin-Etsu Chemical Co., Ltd.), N-β-aminoethyl-γ-aminopropyl-triethoxysilane (trade name: KBE-602, manufactured by Shin-Etsu Chemical Co., Ltd.), γ-aminopropyl-trimethoxysilane (trade name: KBM-903, manufactured by Shin-Etsu Chemical Co., Ltd.), γ-aminopropyl-triethoxysilane (trade name: KBE-903, manufactured by Shin-Etsu Chemical Co., Ltd.), 3-methacryloxypropyltrimethoxys lane (trade name: KBM-503, manufactured by Shin-Etsu Chemical Co., Ltd.), glycidoxyoctyltrimethoxysilane (trade name: KBM-4803, manufactured by Shin-Etsu Chemical Co., Ltd.), 2-(3,4-epoxycyclohexyl)ethyltrimethoxysilane (trade name: KBM-303, manufactured by Shin-Etsu Chemical Co., Ltd.), 3-glycidoxypropyltrimethoxysilane (trade name: KBM-403, manufactured by Shin-Etsu Chemical Co., Ltd.), and 3-glycidoxypropyltriethoxysilane (trade name: KBE-403, manufactured by Shin-Etsu Chemical Co., Ltd.).

Other suitable aspects of the silane coupling agent include a silane coupling agent Y having at least a silicon atom, a nitrogen atom, and a curable functional group, as well as a hydrolyzable group bonded to the silicon atom in the molecule.

This silane coupling agent Y may have at least one silicon atom in the molecule, and the silicon atom may be bonded to the following atoms and substituents. They may be the same or different atoms or substituents. Examples of the atoms and substituents to which the silane coupling agent Y may be bonded include a hydrogen atom, a halogen atom, a hydroxyl group, an alkyl group having 1 to 20 carbon atoms, an alkenyl group, an alkynyl group, an aryl group, an amino group which can be substituted with an alkyl group and/or an aryl group, a silyl group, an alkoxy group having 1 to 20 carbon atoms, and an aryloxy group. These substituent may also further be substituted with a silyl group, an alkenyl group, an alkynyl group, an aryl group, an alkoxy group, an aryloxy group, a thioalkoxy group, an amino group which can be substituted with an alkyl group and/or an aryl group, a halogen atom, a sulfonamide group, an alkoxycarbonyl group, an amide group, a urea group, an ammonium group, an alkylammonium group, a carboxyl group or a salt thereof, a sulfo group or a salt thereof, or the like.

In addition, at least one hydrolyzable group is bonded to the silicon atom. The definition of the hydrolyzable group is as described above.

The silane coupling agent Y may include a group represented by Formula (Z).

The silane coupling agent Y has at least one nitrogen atom in the molecule, and the nitrogen atom is preferably present in the form of a secondary amino group or a tertiary amino group. That is, the nitrogen atom preferably has at least one organic group as a substituent. Further, the structure of the amino group may be present in the form of a partial structure of a nitrogen-containing heterocyclic ring in a molecule, or may also be present as a substituted amino group such as aniline.

Here, examples of the organic group include an alkyl group, an alkenyl group, an alkynyl group, an aryl group, or a combination thereof. These may further have a substituent, and examples of the substituent which can be introduced include a silyl group, an alkenyl group, an alkynyl group, an aryl group, an alkoxy group, an aryloxy group, a thioalkoxy group, an amino group, a halogen atom, a sulfonamide group, an alkoxycarbonyl group, a carbonyloxy group, an amide group, a urea group, an alkyleneoxy group, an ammonium group, an alkylammonium group, a carboxyl group or a salt thereof, and a sulfo group.

In addition, the nitrogen atom is preferably bonded to the curable functional group via an arbitrary organic linking group. Preferred examples of the organic linking group include the above-mentioned substituents which can be introduced to the nitrogen atom and an organic group bonded thereto.

The definition of the curable functional group contained in the silane coupling agent Y is as described above and a suitable range of the group is as described above.

The silane coupling agent Y may have at least one curable functional group in one molecule thereof. Further, an aspect in which the silane coupling agent Y has two or more curable functional groups can be employed, and from the viewpoints of sensitivity and stability, an aspect in which the silane coupling agent Y has 2 to 20 curable functional groups is preferable, an aspect in which the silane coupling agent Y has 4 to 15 curable functional groups is more preferable, and an aspect in which the silane coupling agent Y has 6 to 10 curable functional groups in a molecule is still more preferable.

The molecular weights of the silane coupling agent X and the silane coupling agent Y are not particularly limited, and may include the above-mentioned ranges (a range of 270 or more being preferable).

The content of the silane coupling agent in the composition is preferably 0.1% to 10% by mass, more preferably 0.5% to 8% by mass, still more preferably 1.0% to 6% by mass, and particularly preferably 2% to 6% by mass, with respect to the total solid content of the composition.

The composition may include one kind or two or more kinds of the silane coupling agent. In a case where the composition includes two or more kinds of the silane coupling agent, a total amount thereof may be any one within the above range.

Furthermore, the mass ratio (the mass of the silane coupling agent/the mass of the curable compound) of the silane coupling agent to the above-mentioned curable compound in the composition is preferably 0.1 to 20; from the viewpoint of satisfying both of low reflectivity and linearity, the mass ratio is more preferably 0.2 to 15; and from the viewpoint of satisfying all of low reflectivity, linearity, and suppression of chipping, the mass ratio is still more preferably 0.3 to 10.

<Black Pigment>

Various known black pigments can be used as a black pigment. In particular, from the viewpoint of achieving a high optical density with a small amount of the pigment, carbon black, titanium black, titanium oxide, iron oxide, manganese oxide, graphite, and the like are preferable. Among these, at least one of the carbon black or the titanium black is more preferable, and the titanium black is particularly preferable.

More specifically, organic pigments such as C. I. Pigment Black 1 and inorganic pigments such as Pigment Black 7, which are commercially available products, can also be used.

The black pigment preferably includes titanium black.

The titanium black is a black particle containing a titanium atom. Preferably, it is substoichiometric titanium oxide, titanium oxynitride, or the like. The titanium black particle can modify the surface, if desired, for the purpose of improving the dispersibility, suppressing aggregating properties, and the like. For example, it is possible to coat the titanium black particle with silicon oxide, titanium oxide, germanium oxynitride, aluminum oxide, magnesium oxide, or zirconium oxide, and it is also possible to perform a treatment with a water-repellent material as shown in JP2007-302836A.

The titanium black is typically a titanium black particle, and it is preferable that the primary particle diameter of each particle and the average primary particle diameter are both small.

Specifically, the average primary particle diameter is preferably in the range of 10 nm to 45 nm. Further, the particle diameter in the present invention, that is, the particle diameter refers to the diameter of a circle having an area equal to the projected area of the outer surface of the particle. The projected area of the particle is obtained by measuring the area of the particle taken in an electron micrograph and correcting the imaging magnification.

The specific surface area of the titanium black is not particularly limited, and the value measured by BET method is usually in the order of from 5 m²/g to 150 m²/g, and preferably from 20 m²/g to 120 m²/g so that the water repellency of the titanium black after the surface treatment using a water-repellent agent exhibits a predetermined performance.

Examples of a commercially available product of the titanium black include Titanium Black 10S, 12S, 13R, 13M, 13M-C, 13R, 13R-N, and 13M-T (trade names, manufactured by Mitsubishi Materials Corporation), and Tilack D (trade name, manufactured by Akokasei Co., Ltd.).

Furthermore, it is preferable that the titanium black is contained as a dispersoid including the titanium black and Si atoms.

In this form, the titanium black is contained as a dispersoid in a composition, and the content ratio (Si/Ti) in the Si atoms to the Ti atoms in the dispersoid is preferably 0.05 or more in terms of mass.

Here, the dispersoid includes both the titanium black in a state of primary particles and the titanium black in a state of aggregates (secondary particles).

Furthermore, the upper limit of the content ratio (Si/Ti) of the Si atoms to the Ti atoms in the dispersoid in the present invention is preferably 0.5 since it tends to be easy to produce a pigment dispersion using the dispersoid when the content ratio is 0.5 or less.

In addition, from the viewpoint that when a light-shielding film obtained using the dispersoid is patterned by photolithography or the like, a residue hardly remains in a removal section and the light-shielding properties are excellent, the Si/Ti of the dispersoid is more preferably from 0.05 to 0.5, and still more preferably from 0.07 to 0.4.

To change the Si/Ti of the dispersoid (for example, to 0.05 or more), it is possible to use the following means.

First, a mixture is obtained by dispersing titanium oxide and silica particles with a dispersing machine, and then the mixture is subjected to a reducing process at a high temperature (for example, 850° C. to 1,000° C.). Thus, the dispersoid having the titanium black particles as a main component and containing Si and Ti can be obtained.

Here, specific aspects for changing the Si/Ti of the dispersoid will be described.

The titanium black with the Si/Ti adjusted to, for example, 0.05 or more can be manufactured by the methods described in, for example, paragraphs [0005], and [0016] to [0021] of JP2008-266045A.

In the present invention, by adjusting the content ratio (Si/Ti) of the Si atoms to the Ti atoms in the dispersoid containing the titanium black and the Si atoms to a suitable range (for example, 0.05 or more), the amount of the residue derived from the composition, remaining on the outside of a region where the light-shielding film is formed is reduced when the light-shielding film is formed by using the composition including the dispersoid. Further, the residue includes a component derived from the titanium black particles and/or a composition such as a resin component.

The reason why the amount of the residue is reduced has not been clarified yet, but the above-mentioned dispersoid tends to have a small particle diameter (for example, a particle diameter of 30 nm or less), and the adsorptivity to the underlying film of the whole film decreases as the component containing the Si atoms increases in the dispersoid. This is assumed to contribute to improvement of the development removability of uncured composition (in particular, the titanium black) in the formation of the light-shielding film.

Furthermore, from the viewpoint that the titanium black has excellent light-shielding properties to light in wavelength ranges widely ranging from ultraviolet rays to infrared light, the light-shielding film formed using the dispersoid (preferably with the Si/Ti ratio of 0.05 or more in terms of mass) including the titanium black and Si atoms exerts excellent light-shielding properties.

Furthermore, the content ratio (Si/Ti) of the Si atoms to the Ti atoms in the dispersoid can be measured using, for example, the method (1-1) or the method (1-2) described in paragraph 0033 of JP2013-249417A.

In addition, for the dispersoid contained in the light-shielding film obtained by curing the composition, it is determined whether the content ratio (Si/Ti) of the Si atoms to the Ti atoms in the dispersoid is 0.05 or more, using the method (2) described in paragraph 0035 of JP2013-249417A.

In the dispersoid including the titanium black and the Si atom, the titanium black as described above can be used.

Furthermore, in this dispersoid, one kind or two or more kinds of composite oxides such as Cu, Fe, Mn, V, and Ni, cobalt oxide, iron oxide, a black pigment composed of carbon black, aniline black, or the like may be combined as the dispersoid with the titanium black, for the purpose of adjusting dispersibility, colorability, and the like.

In this case, it is preferable that the dispersoid composed of the titanium black occupies 50% by mass or more of the whole dispersoid.

Incidentally, in the dispersoid, another colorant (such as an organic pigment and a dye) may be used together with the titanium black as desired as long as the colorant does not impair the effects of the present invention, for the purpose of adjusting light-shielding properties or the like.

Hereinafter, the materials used in introducing the Si atoms into the dispersoid will be described. When the Si atoms are introduced into the dispersoid, a Si-containing material such as silica may be used.

Examples of the silica used herein include precipitated silica, fumed silica, colloidal silica, and synthetic silica, and may be selected as appropriate.

Furthermore, since the light-shielding properties are more excellent if the particle diameter of the silica particle is smaller than the thickness of the film in the formation of a light-shielding film, it is preferable to use fine particle-type silica as the silica particle. Further, examples of the fine particle-type silica include the silica described in paragraph 0039 of JP2013-249417A, the contents of which are incorporated herein by reference.

The composition of the present invention may contain one kind or two or more kinds of the titanium black.

In addition to the black pigment, an extender pigment may also be included as necessary to the composition of the present invention. Examples of the extender pigment include barium sulfate, barium carbonate, calcium carbonate, silica, basic magnesium carbonate, alumina white, gloss white, titanium white, and hydrotalcite. These extender pigments can be used singly or in combination of two or more thereof. The amount of the extender pigment to be used is 0 to 100 parts by mass, preferably 5 to 50 parts by mass, and more preferably 10 to 40 parts by mass, with respect to 100 parts by mass of the black pigment. In the present invention, the surfaces of the black pigment and the extender pigments may be modified with a polymer and then used, in some cases.

In addition to the black pigment, organic coloring pigments in red, blue, yellow, green, violet, and the like may be included as necessary. In a case of using the organic coloring pigment, it is preferable to use 1% to 40% by mass of a red pigment with respect to the black pigment, and it is preferable the red pigment is Pigment Red 254.

The content of the black pigment in the composition is preferably 20% to 80% by mass, more preferably 30% to 70% by mass, and still more preferably 35% to 60% by mass, with respect to the total solid content of the composition.

<Other Optional Components>

The curable composition may also include components other than the curable compounds, the silane coupling agent, and the black pigment as described above.

Hereinafter, various optional components will be described in detail.

<Polymerizable Compound>

The composition of the present invention may also a polymerizable compound. The polymerizable compound is a compound which is different from the above-mentioned curable compound. Further, it is preferable that the polymerizable compound does not all of a fluorine atom, a silicon atom, a linear alkyl group having 8 or more carbon atoms, and a branched alkyl group having 3 or more carbon atoms.

The polymerizable compound is preferably a compound which has at least one addition-polymerizable, ethylenically unsaturated group and a boiling point of 100° C. or higher at normal pressure.

Examples of the compound which has at least one addition-polymerizable, ethylenically unsaturated group and a boiling point of 100° C. or higher at normal pressure include monofunctional acrylates or methacrylates such as polyethylene glycol mono(meth)acrylate, polypropylene glycol mono(meth)acrylate, and phenoxyethyl (meth)acrylate; polyethylene glycol di(meth)acrylate, trimethylolethane tri(meth)acrylate, neopentyl glycol di(meth)acrylate, pentaerythritol tri(meth)acrylate, pentaerythritol tetra(meth)acrylate, dipentaerythritol hexa(meth)acrylate, hexanediol (meth)acrylate, trimethylolpropane tri(acryloyloxypropyl) ether, tri(acryloyloxyethyl) isocyanurate, and a compound obtained by (meth)acrylation after the addition of ethylene oxide or propylene oxide to polyfunctional alcohol such as glycerin or trimethylol ethane, poly(meth)acrylates of pentaerythritol or dipentaerythritol, the urethane acrylates described in each publication of JP1973-41708B (JP-S48-41708B), JP1975-6034B (JP-S50-6034B), and JP1976-37193A (JP-S51-37193A), the polyester acrylates described in each publication of JP1973-64183A (JP-S48-64183A), JP1974-43191B (JP-S49-43191B), and JP1977-30490B (JP-S52-30490B), and polyfunctional acrylates or methacrylates such as epoxy acrylates which are reaction products obtained from an epoxy resin and a (meth)acrylic acid. In addition, those introduced as the photocurable monomers and oligomers in pages 300 to 308 in Journal of the Adhesion Society of Japan, Vol. 20, No. 7 can also be used.

Furthermore, a compound obtained by (meth)acrylation after the addition of ethylene oxide or propylene oxide to the polyfunctional alcohol represented by General Formulae (1) and (2) described together with the specific examples thereof in JP1998-62986A (JP-H10-62986A) can also be used.

Among those, dipentaerythritol penta(meth)acrylate, dipentaerythritol hexa(meth)acrylate, and structures in which the acryloyl groups thereof are linked to dipentaerythritol via an ethylene glycol residue or a propylene glycol residue are preferable. These oligomer types thereof can also be used.

Furthermore, the urethane acrylates described in each publication of JP1973-41708B (JP-S48-41708B), JP1976-37193A (JP-S51-37193A), JP1990-32293B (JP-H02-32293B), and JP1990-16765B (JP-H02-16765B), and the urethane compounds having an ethylene oxide-based skeleton described in each publication of JP1983-49860B (JP-S58-49860B), JP1981-17654B (JP-S56-17654B), JP1987-39417B (JP-S62-39417B), and JP1987-39418B (JP-S62-39418B) are also suitable. A photopolymerizable composition excellent in photosensitive speed can be obtained by using an addition polymerizable compound having an amino structure or a sulfide structure in a molecule as described in each publication of JP1988-277653A (JP-S63-277653A), JP1988-260909A (JP-S63-260909A), and JP1989-105238A (JP-H01-105238A). Examples of the commercially available products thereof include Urethane Oligomers UAS-10 and UAB-140 (trade names, manufactured by Nippon Paper Chemicals Ltd.), UA-7200 (manufactured by Shin-Nakamura Chemical Industry Co., Ltd.), DPHA-40H (trade name, manufactured by Nippon Kayaku Co., Ltd.), and UA-306H, UA-306T, UA-3061, AH-600, T-600, and AI-600 (trade names, manufactured by Kyoeisha Chemical Co., Ltd.).

In addition, ethylenically unsaturated compounds having an acid group are also suitable. Examples of the commercially available products thereof include TO-756 which is a carboxyl group-containing trifunctional acrylate and TO-1382 which is a carboxyl group-containing pentafunctional acrylate, both manufactured by TOAGOSEI Co., Ltd. As for the polymerizable compound used in the present invention, tetrafunctional or higher acrylate compounds are more preferable.

The polymerizable compounds may be used singly or in combination of two or more kinds thereof.

In a case where a combination of two or more polymerizable compounds is used, a combination aspect thereof can be determined as appropriate in accordance with the physical properties or the like required for the composition. Examples of the suitable combination aspects of the polymerizable compounds may be a combination aspect of two or more kinds of polymerizable compounds selected from the above-mentioned polyfunctional acrylate compounds, and for example, it may be a combination of dipentaerythritol hexaacrylate and pentaerythritol triacrylate.

The content of the polymerizable compound in the composition of the present invention is preferably 3% by mass to 55% by mass, and more preferably 10% by mass to 50% by mass, with respect to the total solid content of the composition.

<Polymerization Initiator>

The composition of the present invention may contain a polymerization initiator.

The polymerization initiator is not particularly limited and can be appropriately selected from known polymerization initiators, and for example, a polymerization initiator having photosensitivity (a so-called photopolymerization initiator) is preferable.

The photopolymerization initiator is not particularly limited as long as it has a function of initiating polymerization of the polymerizable compound, and can be appropriately selected from known photopolymerization initiators. For example, a photopolymerization initiator having photosensitivity with respect to light rays in a range ranging from an ultraviolet ray region to visible light are preferable. Further, the photopolymerization initiator may be either an activator which interacts with a photo-excited sensitizer in a certain action and produces active radicals or an initiator which initiates cationic polymerization according to the type of monomer.

In addition, it is preferable that the photopolymerization initiator contains at least one kind of compound having at least a molar light absorption coefficient of about 50 in a range from about 300 nm to about 800 nm (more preferably 330 nm to 500 nm).

Examples of the photopolymerization initiator include halogenated hydrocarbon derivatives (for example, a derivative having a triazine skeleton and a derivative having an oxadiazole skeleton), acylphosphine compounds such as acylphosphine oxide, oxime compounds such as hexaaryl biimidazole and an oxime derivative, organic peroxide, thio compounds, ketone compounds, aromatic onium salts, ketoxime ethers, aminoacetophenone compounds, and hydroxyacetophenone. Examples of the halogenated hydrocarbon compound having a triazine skeleton include the compounds described in Wakabayashi et al., Bull. Chem. Soc. Japan, 42, 2924 (1969), the compounds described in UK1388492B, the compound described in JP1978-133428A (JP-S53-133428A), the compounds described in GE3337024B, the compounds described in F. C. Schaefer et al., J. Org. Chem.; 29, 1527 (1964), the compounds described in JP1987-58241A (JP-S62-58241A), the compounds described in JP1993-281728A (JP-H05-281728A), the compounds described in JP1993-34920A (JP-H05-34920A), and the compounds described in U.S. Pat. No. 4,212,976A.

Furthermore, from the viewpoint of exposure sensitivity, a compound selected from the group consisting of a trihalomethyl triazine compound, a benzyl dimethyl ketal compound, an α-hydroxyketone compound, an α-aminoketone compound, an acylphosphine compound, a phosphine oxide compound, a metallocene compound, an oxime compound, a triallyl imidazole dimer, an onium compound, a benzothiazole compound, a benzophenone compound, an acetophenone compound, and derivatives of these, a cyclopentadiene-benzene-iron complex and a salt thereof, a halomethyl oxadiazole compound, and a 3-aryl-substituted coumarin compound are preferable.

More preferably, at least one kind of compound which is a trihalomethyl triazine compound, an α-aminoketone compound, an acylphosphine compound, a phosphine oxide compound, an oxime compound, a triallyl imidazole dimer, an onium compound, a benzophenone compound, or an acetophenone compound, and is selected from the group consisting of a trihalomethyl triazine compound, an α-aminoketone compound, an oxime compound, a triallyl imidazole dimer, and a benzophenone compound is particularly preferable.

In particular, in a case where the composition of the present invention is used for the manufacture of a light-shielding film of a solid-state imaging element, a micropattern needs to be formed in a sharp shape. Accordingly, it is important for the composition to have curability and to be developed without residues in an unexposed area. From such a viewpoint, it is preferable to use an oxime compound as a photopolymerization initiator. Particularly, in a case where a micropattern is formed in the solid-state imaging element, stepper exposure is used for exposure for curing. However, the exposure machine may be damaged by halogen in some cases, and the amount of the photopolymerization initiator to be added is required to be reduced. Taking this point into consideration, for forming a micropattern like a solid-state imaging element, it is preferable to use an oxime compound as the photopolymerization initiator in order to form a micropattem such as the solid-state imaging element. Further, by using the oxime compound, color migration properties can be improved.

With regard to specific examples of the photopolymerization initiator, reference can be made to the description in for example, paragraphs 0265 to 0268 of JP2013-29760A, the contents of which are incorporated herein by reference.

As the photopolymerization initiator, a hydroxyacetophenone compound, an aminoacetophenone compound, and an acylphosphine compound can also suitably be used. More specifically, for example, the aminoacetophenone-based initiators described in JP1998-291969A (JP-H10-291969A) and the acylphosphine-based initiators described in JP4225898B can also be used.

As the hydroxyacetophenone-based initiator, IRGACURE-184, DAROCUR-1173, IRGACURE-500, IRGACURE-2959, and IRGACURE-127 (trade names, all manufactured by BASF) can be used.

As the aminoacetophenone-based initiator, IRGACURE-907, IRGACURE-369, and IRGACURE-379EG (trade names, all manufactured by BASF) which are commercially available products can be used. In addition, as the aminoacetophenone-based initiator, the compound described in JP2009-191179A, of which an absorption wavelength matches with a light source of a long wavelength of 365 nm, 405 nm, or the like can be used.

IRGACURE-819 or DAROCUR-TPO (trade name, all manufactured by BASF) which are commercially available products can be used as the acylphosphine-based initiator.

More preferred examples of the photopolymerization initiator include oxime compounds (oxime-based initiators), as described above. The oxime compounds are preferable from the viewpoint that the polymerization efficiency is high with high sensitivity, and curing can be performed irrespective of the concentration of a color material, which makes it easier to design the concentration of the color material to be higher.

As the specific examples of the oxime compounds, the compound described in JP2001-233842A, the compound described in JP2000-80068A, and the compound described in JP2006-342166A can be used.

Examples of the oxime compound which can be suitably used in the present invention include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-(4-toluenesulfonyloxy)iminobutan-2-one, and 2-ethoxycarbonyloxyimino-1-phenylpropan-1-one.

Furthermore, examples of the oxime compound also include the compounds described in J. C. S. Perkin II (1979), pp. 1653-1660, J. C. S. Perkin II (1979), pp. 156-162, Journal of Photopolymer Science and Technology (1995), pp. 202-232, and each publication of JP2000-66385A, JP2000-80068A, JP2004-534797A, and JP2006-342166A, and the like.

As the commercially available products thereof, IRGACURE-OXE01 (manufactured by BASF) and IRGACURE-OXE02 (manufactured by BASF) are also suitably used. In addition, TR-PBG-304 (manufactured by Changzhou Tronly New Electronic Materials Co., Ltd.), ADEKA ARKLS NCI-831, and ADEKA ARKLS NCI-930 (manufactured by ADEKA Corporation) can also be used.

Further, as oxime compounds other than the above, the compound described in JP2009-519904A in which oxime is linked to an N-position of carbazole, the compound described in U.S. Pat. No. 7,626,957B in which a hetero-substituent is introduced into a benzophenone moiety, the compounds described in JP2010-15025A and US2009/292039A in which a nitro group is introduced into a dye moiety, the ketoxime compound described in WO2009/131189A, the compound described in U.S. Pat. No. 7,556,910B, which contains a triazine skeleton and an oxime skeleton in the same molecule, the compound described in JP2009-221114A, which has maximum absorption at 405 nm and has excellent sensitivity to a light source of a g-ray, and the like, may be used.

With regard to preferred examples thereof, reference can be made to paragraphs 0274 to 0275 of JP2013-29760A, the contents of which are incorporated herein by reference.

Specifically, the oxime compound is preferably a compound represented by the following Formula (OX-1). Incidentally, the compound may be an oxime compound in which an N—O bond of oxime forms an (E) isomer, an oxime compound in which the N—O bond forms a (Z) isomer, or an oxime compound in which the N—O bond forms a mixture of an (E) isomer and a (Z) isomer.

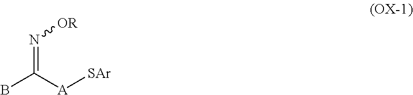

In General Formula (OX-1), R and B each independently represent a monovalent substituent, A represents a divalent organic group, and Ar represents an aryl group.

In General Formula (OX-1), the monovalent substituent represented by R is preferably a monovalent non-metal atomic group.

Examples of the monovalent non-metal atomic group include an alkyl group, an aryl group, an acyl group, an alkoxycarbonyl group, an aryloxycarbonyl group, a heterocyclic group, an alkylthiocarbonyl group, and an arylthiocarbonyl group. Further, these groups may have one or more substituents. Moreover, the above substituents may further be substituted with other substituents.

Examples of the substituents include a halogen atom, an aryloxy group, an alkoxycarbonyl group, an aryloxycarbonyl group, an acyloxy group, an acyl group, an alkyl group, and an aryl group.

As the monovalent substituent represented by B in General Formula (OX-1), an aryl group, a heterocyclic group, an arylcarbonyl group, or a heterocyclic carbonyl group is preferable. These groups may have one or more substituents. Examples of the substituent include the above-mentioned substituents.

As the divalent organic group represented by A in General Formula (OX-1), an alkylene group having 1 to 12 carbon atoms, a cycloalkylene group, or an alkynylene group is preferable. These groups may have one or more substituents. Examples of the substituent include the above-mentioned substituents.

In the present invention, an oxime compound having a fluorine atom can also be used as the photopolymerization initiator. Specific examples of the oxime compound having a fluorine atom include the compounds described in JP2010-262028A, the compounds 24, and 36 to 40 described in JP2014-500852A, and the compounds (C-3) described in JP2013-164471A, the contents of which are incorporated herein by reference.

As the photopolymerization initiator, a compound represented by the following Formula (1) or (2) can also be used.

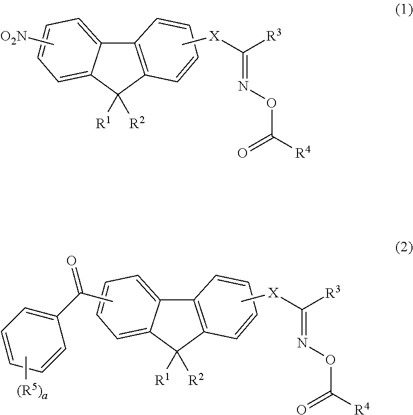

In Formula (1), R¹ and R² each independently represent an alkyl group having 1 to 20 carbon atoms, an alicyclic hydrocarbon group having 4 to 20 carbon atoms, an aryl group having 6 to 30 carbon atoms, or an arylalkyl group having 7 to 30 carbon atoms, and in the case where R¹ and R² are phenyl groups, the phenyl groups may be bonded to each other to form a fluorene group; and R³ and R⁴ each independently represent a hydrogen atom, an alkyl group having 1 to 20 carbon atoms, an aryl group having 6 to 30 carbon atoms, an arylalkyl group having 7 to 30 carbon atoms, or a heterocyclic group having 4 to 20 carbon atoms; and X represents a direct bond or a carbonyl group.

In Formula (2), R¹, R², R³, and R⁴ have the same definitions as R¹, R², R³, and R⁴ in Formula (1); R⁵ represents —R⁶, —OR⁶, —SR⁶, —COR⁶, —CONR⁶R⁶, —NR⁶COR⁶, —OCOR⁶, —COOR⁶, —SCOR⁶, —OCSR⁶, —COSR⁶, —CSOR⁶, —CN, a halogen atom, or a hydroxyl group; R⁶ represents an alkyl group having 1 to 20 carbon atoms, an aryl group having 6 to 30 carbon atoms, an arylalkyl group having 7 to 30 carbon atoms, or a heterocyclic group having 4 to 20 carbon atoms; X represents a direct bond or a carbonyl group; and a represents an integer of 0 to 4.

In Formulae (1) and (2), R¹ and R² are each independently preferably a methyl group, an ethyl group, an n-propyl group, an i-propyl, a cyclohexyl group, or a phenyl group. R³ is preferably a methyl group, an ethyl group, a phenyl group, a tolyl group, or a xylyl group. R⁴ is preferably an alkyl group having 1 to 6 carbon atoms or a phenyl group. R⁵ is preferably a methyl group, an ethyl group, a phenyl group, a tolyl group, or a naphthyl group. X is preferably a direct bond.

Specific examples of the compounds represented by Formulae (1) and (2) include the compounds described in paragraphs 0076 to 0079 of JP2014-137466A, the contents of which are incorporated herein by reference.

Specific examples of the oxime compound which is preferably used in the present invention are shown below, but the present invention is not limited thereto.

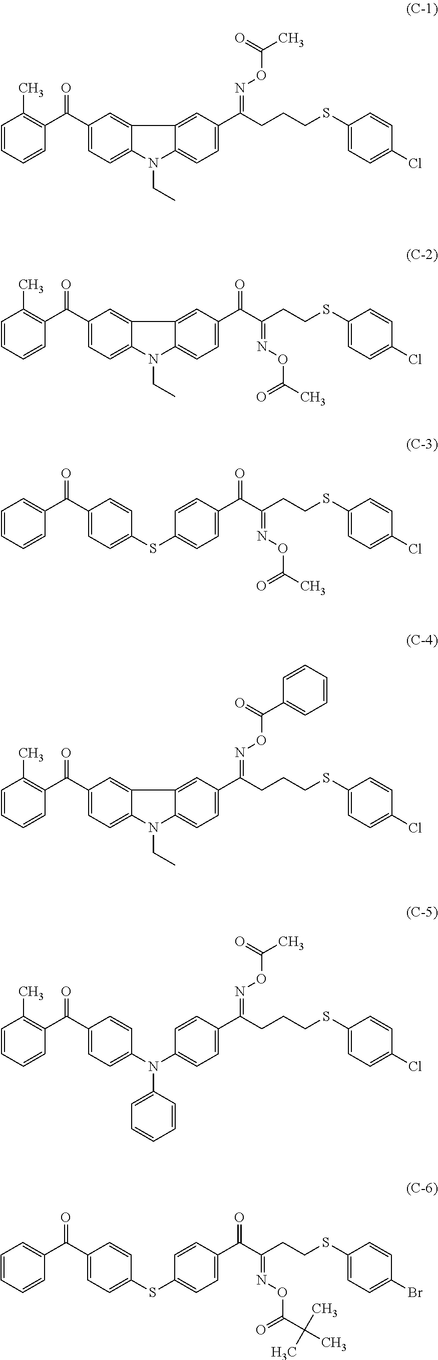 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

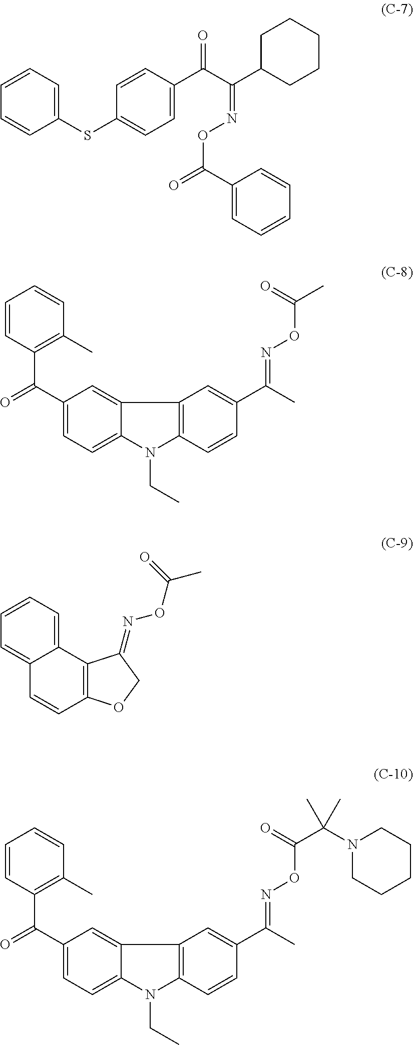 [SMILES: O=C(O/N=C(\C(=O)c1ccc(Sc2ccccc2)cc1)C1CCCCC1)c1ccccc1 ; CCn1c2ccc(C(=O)c3ccccc3C)cc2c2cc(/C(C)=N/OC(C)=O)ccc21 ; CC(=O)O/N=C1\COc2ccc3ccccc3c21 ; CCn1c2ccc(C(=O)c3ccccc3C)cc2c2cc(/C(C)=N/OC(=O)C(C)(C)N3CCCCC3)ccc21]

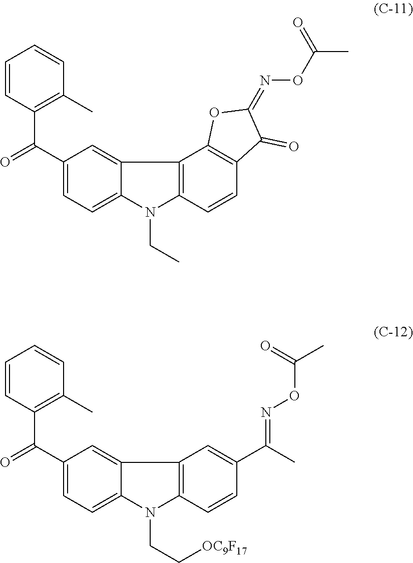

The oxime compound has a maximum absorption wavelength in a wavelength range of preferably 350 nm to 500 nm, and more preferably in a wavelength range of 360 nm to 480 nm, and an oxime compound showing a high absorbance at 365 nm and 405 nm is particularly preferable.

From the viewpoint of sensitivity, the molar light absorption coefficient at 365 nm or 405 nm of the oxime compound is preferably 1,000 to 300,000, more preferably 2,000 to 300,000, and still more preferably 5,000 to 200,000.

The molar light absorption coefficient of the oxime compound can be measured using a known method. Specifically, it is preferable to measure the molar light absorption coefficient by means of, for example, an ultraviolet and visible light spectrophotometer (Cary-5 spectrophotometer manufactured by Varian) by using an ethyl acetate solvent at a concentration of 0.01 g/L.

The content of the polymerization initiator is preferably 0.1% to 50% by mass, more preferably 0.5% to 30% by mass, and still more preferably 1% to 20% by mass, with respect to the total solid content of the composition. With the content within this range, better sensitivity and pattern forming properties are obtained. The composition of the present invention may include one kind or two or more kinds of the polymerization initiator. In a case where the composition includes two or more kinds of the polymerization initiator, the total amount thereof is preferably within the above range.

<Resin>

The composition of the present invention preferably contains a resin. Further, the resin is not included in the curable compound and the silane coupling agent as described above.

Examples of the resin include a dispersant that contributes to the dispersibility of a black pigment, and a binder polymer. Further, the alkali-soluble resin which will be described later may be included as a pigment dispersant.

Hereinafter, these will be described in detail.

(Dispersant)

The composition of the present invention preferably contains a dispersant. The dispersant contributes to improvement of the dispersibility of black pigments such as the above-mentioned titanium black.

As the dispersant, for example, a known pigment dispersant can be appropriately selected and used. Among those, a polymer compound is preferable.

Examples of the dispersant include polymer dispersants [for example, a polyamidoamine and a salt thereof, a polycarboxylic acid and a salt thereof, a high-molecular-weight unsaturated acid ester, a modified polyurethane, a modified polyester, a modified poly(meth)acrylate, a (meth)acrylic copolymer, and a naphthalenesulfonic acid/formalin condensate], a polyoxyethylene alkyl phosphate ester, a polyoxyethylene alkylamine, and a pigment derivative.

The polymer dispersant can further be classified into a linear polymer, a terminal-modified polymer, a graft-type polymer, and a block-type polymer, depending on its structure.

The polymer compound is adsorbed on a surface of the dispersoid such as the black pigment and a pigment which is used in combination according to purposes, and acts so as to prevent re-aggregation. For this reason, examples of a preferable structure thereof include a terminal-modified polymer, a graft-type polymer, and a block-type polymer, which have an anchoring site for a pigment surface.

On the other hand, the adsorptivity of the polymer compound onto the dispersoid can also be enhanced by modifying the surface of titanium black or the above-described dispersoid including the titanium black and Si atoms.

The polymer compound preferably has a structural unit with a graft chain. Further, in the present specification, the “structural unit” has the same definition as the “repeating unit”.

Such a polymer compound having a structural unit with a graft chain has an affinity for a solvent due to the graft chain, so that the polymer compound is excellent in the dispersibility of the black pigment and the dispersion stability over time. Further, due to the presence of a graft chain, the composition has an affinity for a polymerizable compound, other resins which can be possibly combined, or the like, so that it is less likely that the alkali development generates a residue.

If the graft chain is long, a steric repulsion effect is high and the dispersibility is improved. However, if the graft chain is too long, the adsorption force to the black pigment is reduced, so that the dispersibility tends to be lowered. As a result, the number of atoms other than hydrogen atoms in the graft chain is preferably in the range of 40 to 10,000, the number of atoms other than hydrogen atoms is more preferably in the range of 50 to 2,000, and the number of atoms other than hydrogen atoms is still more preferably in the range of 60 to 500.

Here, the graft chain refers to a portion from the base (an atom which is in a group which is branched from the main chain and bonded to the main chain) of the main chain of a copolymer to the end of the group which is branched from the main chain.

The graft chain preferably has a polymer structure, and examples of such the polymer structure include a polyacrylate structure (for example, a poly(meth)acrylic structure), a polyester structure, a polyurethane structure, a polyurea structure, a polyamide structure, and a polyether structure.

In order to improve the interaction between the graft chain and a solvent, thereby increasing the dispersibility, it is preferable that the graft chain is a graft chain having at least one selected from the group consisting of the polyester structure, the polyether structure, and the polyacrylate structure. It is more preferable that the graft chain has at least one of the polyester structure or the polyether structure.

The structure of a macromonomer having such a polymer structure as a graft chain is not particularly limited, but preferably, a macromonomer with a reactive double-bond fainting group can be suitably used.

Examples of commercially available macromonomers which correspond to the structural unit with a graft chain of the polymer compound and are suitable for use in the synthesis of the polymer compound include AA-6 (trade name, TOAGOSEI Co., Ltd.), AA-10 (trade name, manufactured by TOAGOSEI CO., Ltd.), AB-6 (trade name, manufactured by TOAGOSEI Co., Ltd.), AS-6 (trade name, manufactured by TOAGOSEI Co., Ltd.), AN-6 (trade name, manufactured by TOAGOSEI Co., Ltd.), AW-6 (trade name, manufactured by TOAGOSEI Co., Ltd.), AA-714 (trade name, manufactured by TOAGOSEI Co., Ltd.), AY-707 (trade name, manufactured by TOAGOSEI Co., Ltd.), AY-714 (trade name, manufactured by TOAGOSEI Co., Ltd.), AK-5 (trade name, manufactured by TOAGOSEI Co., Ltd.), AK-30 (trade name, manufactured by TOAGOSEI Co., Ltd.), AK-32 (trade name, manufactured by TOAGOSEI Co., Ltd.), BLEMMER PP-100 (trade name, manufactured by NOF Co., Ltd.), BLEMMER PP-500 (trade name, NOF Corporation), BLEMMER PP-800 (trade name, manufactured by NOF Co., Ltd.), BLEMMER PP-1000 (trade name, manufactured by NOF Co., Ltd.), BLEMMER 55-PET-800 (trade name, manufactured by NOF Co., Ltd.), BLEMMER PME-4000 (trade name, manufactured by NOF Co., Ltd.), BLEMMER PSE-400 (trade name, manufactured by NOF Co., Ltd.), BLEMMER PSE-1300 (trade name, manufactured by NOF Co., Ltd.), BLEMMER 43PAPE-600B (trade name, manufactured by NOF Co., Ltd.), and the like. Among those, the AA-6 (trade name, manufactured by TOAGOSEI Co., Ltd.), the AA-10 (trade name, TOAGOSEI Co., Ltd.), the AB-6 (trade name, manufactured by TOAGOSEI Co., Ltd.), the AS-6 (trade name, TOAGOSEI Co., Ltd.), the AN-6 (trade name, manufactured by TOAGOSEI Co. Ltd.), and BLEMMER PME-4000 (trade name, manufactured by NOF Co., Ltd.), are preferably used.

The polymer compound preferably contains a structural unit represented by any one of the following Formulae (1) to (4) as the structural unit with a graft chain, and more preferably contains a structural unit represented by any one of the following Formulae (1A), (2A), (3A), (3B), and (4) as the structural unit with a graft chain.

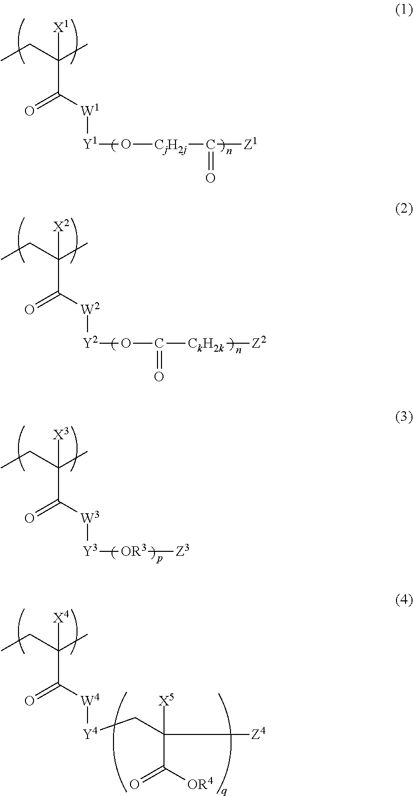

In Formulae (1) to (4), W¹, W², W³, and W⁴ each independently represent an oxygen atom or NH. W¹, W², W³, and W⁴ are preferably each an oxygen atom.

In Formulae (1) to (4), X¹, X², X³, X⁴, and X⁵ each independently represent a hydrogen atom or a monovalent organic group. In terms of constraints of synthesis, it is preferable that X¹, X², X³, X⁴, and X⁵ each independently represent a hydrogen atom or an alkyl group having 1 to 12 carbon atoms. It is more preferable that X¹, X², X³, X⁴, and X⁵ each independently represent a hydrogen atom or a methyl group, with the methyl group being particularly preferable.

In Formulae (1) to (4), Y¹, Y², Y³ and Y⁴ each independently represent a divalent linking group, and the linking group is not particularly limited in terms of its structure. Specific examples of the divalent linking groups represented by Y¹, Y², Y³, and Y⁴ include linking groups represented by the following (Y-1) to (Y-21). In the structures shown below, A and B means binding sites to a left terminal group and a right terminal group, respectively, in Formulae (1) to (4). Among the structures shown below, (Y-2) or (Y-13) is more preferable in terms of easiness of synthesis.

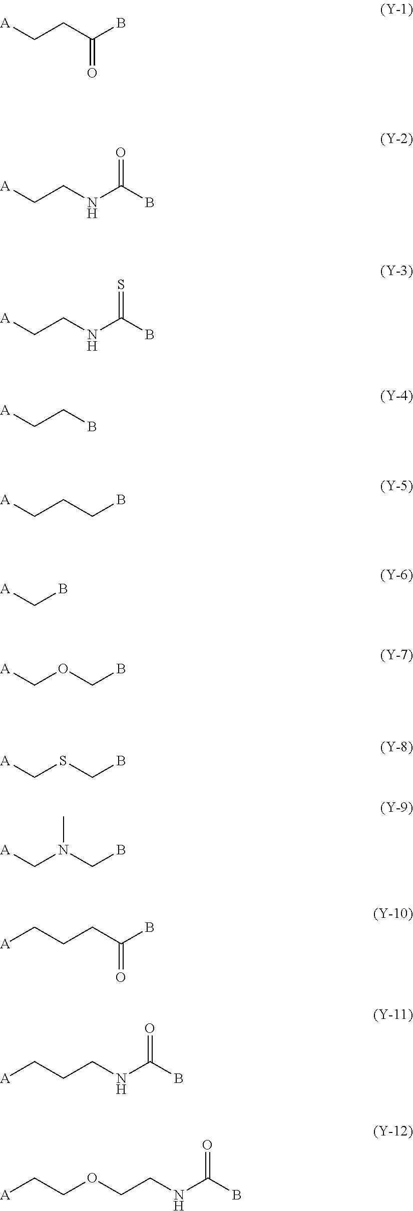

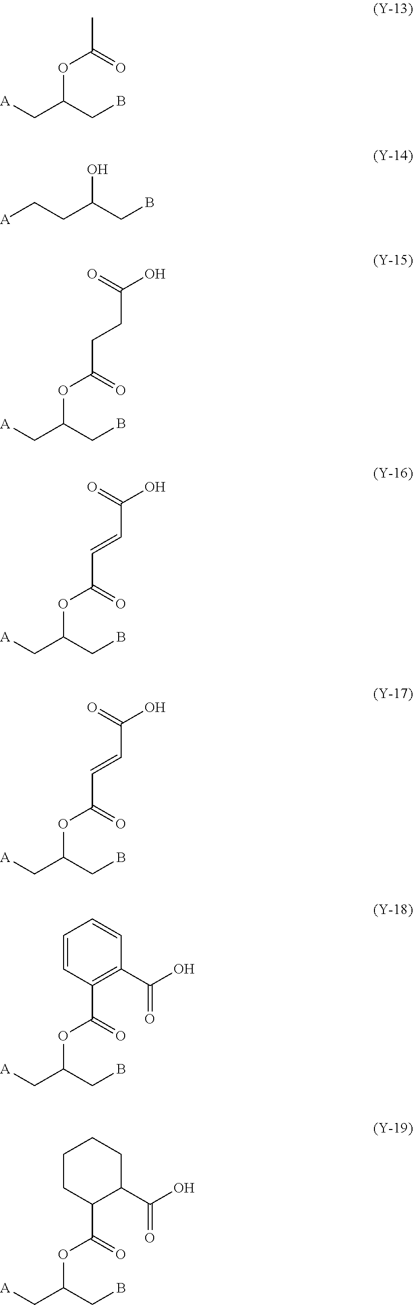

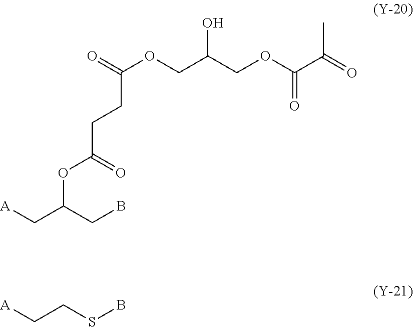

In Formulae (1) to (4), Z¹, Z², Z³, and Z⁴ each independently represent a monovalent organic group. The structure of the organic group is not particularly limited. Specific examples of the organic groups include an alkyl group, a hydroxyl group, an alkoxy group, an aryloxy group, heteroaryloxy group, an alkylthioether group, an arylthioether group, a heteroarylthioether group, and an amino group. Among those, ones having the steric repulsion effect are preferable as the organic groups represented by Z¹, Z², Z³, and Z⁴, in particular from the viewpoint of improving the dispersibility. It is preferable that Z¹, Z², Z³, and Z⁴ each independently represent an alkyl group alkoxy group having 5 to 24 carbon atoms. Among those, it is particularly preferable that Z¹, Z², Z³, and Z⁴ each independently represent a branched alkyl group having 5 to 24 carbon atoms, a cyclic alkyl group having 5 to 24 carbon atoms, or an alkoxy group having 5 to 24 carbon atoms. In addition, the alkyl group contained in the alkoxy group may be linear, branched, or cyclic.

In Formulae (1) to (4), n, m, p, and q are each independently an integer of 1 to 500.

Further, in Formulae (1) and (2), j and k each independently represent an integer of 2 to 8. j and k in Formulae (1) and (2) are preferably an integer of 4 to 6, and most preferably 5, from the viewpoint of dispersion stability and developability.

In Formula (3), R³ represents a branched or linear alkylene group, and is preferably an alkylene group having 1 to 10 carbon atoms, and more preferably an alkylene group having 2 or 3 carbon atoms. When p is 2 to 500, R³ which are present in plural numbers may be the same as or different from each other.

In Formula (4), R⁴ represents a hydrogen atom or a monovalent organic group, and the monovalent organic group is not particularly limited in terms of its structure. R⁴ is preferably a hydrogen atom, an alkyl group, an aryl group, or a heteroaryl group, and more preferably a hydrogen atom or an alkyl group. In a case where R⁴ is an alkyl group, as the alkyl group, a linear alkyl group having 1 to 20 carbon atoms, a branched alkyl group having 3 to 20 carbon atoms, or a cyclic alkyl group having 5 to 20 carbon atoms is preferable, a linear alkyl group having 1 to 20 carbon atoms is more preferable, and a linear alkyl group having 1 to 6 carbon atoms is still more preferable. In Formula (4), when q is 2 to 500, X⁵ and R⁴ which are present in plural numbers in a graft copolymer may be the same as or different from each other.

Moreover, the polymer compound may have two or more structural units with a graft chain, which differ from each other in structure. That is, the structural units represented by Formulae (1) to (4), which differ from each other in structure, may be included in the molecule of the polymer compound. Further, in Formulae (1) to (4), in a case where n, m, p, and q each represent an integer of 2 or more, j and k may include different structures in the side chains in Formulae (1) and (2). In Formulae (3) and (4), R³, R⁴, and X⁵ which are present in plural numbers in the molecules may be the same as or different from each other.

As for the structural unit represented by Formula (1), a structural unit represented by the following Formula (1A) is more preferable from the viewpoints of dispersion stability and developability.

Furthermore, as the structural unit represented by Formula (2), a structural unit represented by the following formula (2A) is more preferable from the viewpoint of dispersion stability and developability.

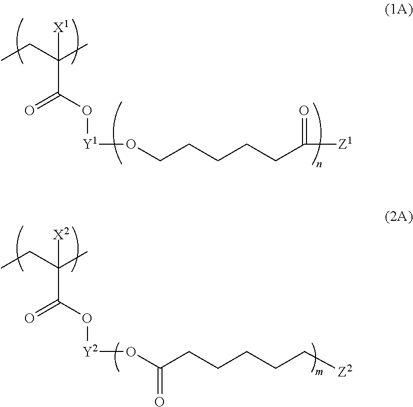

In Formula (1A), X¹, Y¹, Z¹, and n have the same definitions as X¹, Y¹, Z¹, and n in formula (1), and the preferred ranges thereof are the same. In Formula (2A), X², Y², Z², and m have the same definitions as X², Y², Z², and m in Formula (2), and the preferred ranges thereof are the same.

Furthermore, as the structural unit represented by Formula (3), a structural unit represented by the following Formula (3A) or (3B) is more preferable from the viewpoint of dispersion stability and developability.

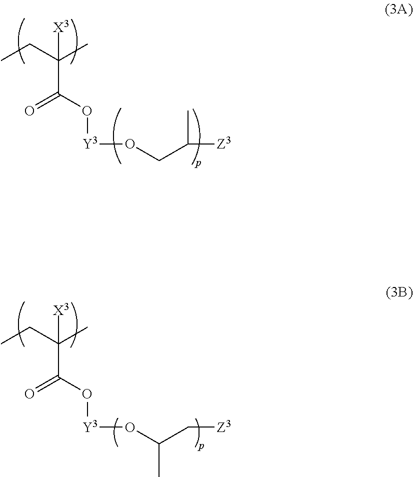

In Formula (3A) or (3B), X³, Y³, Z³, and p have the same definitions as X³, Y³, Z³, and p in Formula (3), and the preferred ranges thereof are the same.

It is more preferable that the polymer compound has the structural unit represented by Formula (1A) as the structural unit having a graft chain.

In the polymer compound, the structural unit with a graft chain (for example, the structural units represented by Formulae (1) to (4)) is included preferably in a range of 2% to 90%, and more preferably in a range of 5% to 30%, in terms of mass, with respect to the total mass of the polymer compound. If the structural unit with a graft chain is included within this range, the dispersibility of the black pigment (in particular, titanium black particles) is high and the developability at the time of forming the light-shielding film is excellent.

Moreover, the polymer compound preferably has a hydrophobic structural unit which differs from the structural unit with a graft chain (that is, which does not correspond to the structural unit with a graft chain). Meanwhile, in the present invention, the hydrophobic structural unit is a structural unit having no acid group (for example, a carboxyl group, a sulfonic acid group, a phosphoric acid group, and a phenolic hydroxyl group).

The hydrophobic structural unit is preferably a structural unit which is derived from (corresponds to) a compound (monomer) having the C log P value of 1.2 or more, and more preferably a structural unit derived from a compound having the C log P value of 1.2 to 8. Thus, the effects of the present invention are expressed with more reliability.

A C log P value is a value calculated by the program “CLOGP”, which is available from Daylight Chemical Information System, Inc. This program provides values of “calculated log P” calculated using Hansch and Leo's fragment approach (see documents below). The fragment approach is based on the chemical structure of a compound, and divides the chemical structure into partial structures (fragments) and sums the log P contribution allocated to each fragment. Thus the log P value of the compound is estimated. The details thereof are described in the following documents. In the present invention, the C log P values calculated by the program CLOGP v4.82 are used.

A. J. Leo, Comprehensive Medicinal Chemistry, Vol. 4, C. Hansch, P. G. Sammnens, J. B. Taylor and C. A. Ramsden, Eds., p. 295, Pergamon Press, 1990 C. Hansch & A. J. Leo. Substituent Constants For Correlation Analysis in Chemistry and Biology. John Wiley & Sons. A. J. Leo. Calculating log Poct from structure. Chem. Rev., 93, 1281-1306, 1993.

The log P refers to the common logarithm of a partition coefficient P. The log P is a value of a physical property, being a quantitative numeric value, representing how an organic compound is distributed in an equilibrium of the two-phase system of oil (typically 1-octanol) and water. The log P is expressed in the following expression.

log P=log(Coil/Cwater)

In the expression, Coil represents the molar concentration of the compound in the oil phase, and Cwater represents the molar concentration of the compound in the water phase.

Oil solubility increases as the value of log P crosses zero and increases in the positive direction and water solubility increases as an absolute value increases in the negative direction. The log P has a negative correlation with the water solubility of the organic compound and is widely used as a parameter for estimating the hydrophilic or hydrophobic properties of an organic compound.

It is preferable that the polymer compound has at least one structural unit selected from structural units derived from monomers represented by the following General Formulae (i) to (iii) as the hydrophobic structural unit.

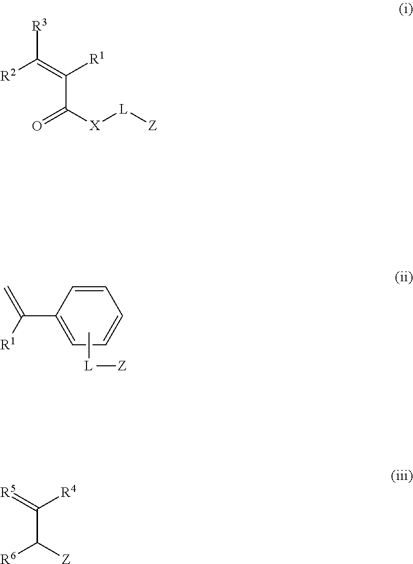

In Formulae (i) to (iii), R¹, R², and R³ each independently represent a hydrogen atom, a halogen atom (for example, fluorine, chlorine, and bromine), or an alkyl group having 1 to 6 carbon atoms (for example, a methyl group, an ethyl group, and a propyl group).

R¹, R², and R³ are each more preferably a hydrogen atom or an alkyl group having 1 to 3 carbon atoms, and most preferably a hydrogen atom or a methyl group. It is more preferable that R² and R³ are each a hydrogen atom.

X represents an oxygen atom (—O—) or an imino group (—NH—), and is preferably an oxygen atom.

L is a single bond or a divalent linking group. Examples of the divalent linking groups include a divalent aliphatic group (for example, an alkylene group, a substituted alkylene group, an alkenylene group, a substituted alkenylene group, an alkynylene group, and a substituted alkynylene group), a divalent aromatic group (for example, an arylene group and a substituted arylene group), a divalent heterocyclic group, an oxygen atom (—O—), a sulfur atom (—S—), an imino group (—NH—), a substituted imino group (—NR³¹—, in which R³¹ is an aliphatic group, an aromatic group, or a heterocyclic group), a carbonyl group (—CO—), and a combination thereof.

The divalent aliphatic group may have a cyclic structure or a branched structure. The number of carbon atoms in the aliphatic group is preferably 1 to 20, more preferably 1 to 15, and still more preferably 1 to 10. The aliphatic group may be a saturated aliphatic group or an unsaturated aliphatic group, but is preferably a saturated aliphatic group. Further, the aliphatic group may have a substituent. Examples of the substituents include a halogen atom, an aromatic group, and a heterocyclic group.

The number of carbon atoms in the divalent aromatic group is preferably 6 to 20, more preferably 6 to 15, and still more preferably 6 to 10. The aromatic group may have a substituent. Examples of the substituents include a halogen atom, an aliphatic group, an aromatic group, and a heterocyclic group.

The divalent heterocyclic group preferably has a 5- or 6-membered ring as the heterocyclic ring. Another heterocyclic ring, an aliphatic ring, or an aromatic ring may be fused with the heterocyclic ring. The heterocyclic group may have a substituent. Examples of the substituents include a halogen atom, a hydroxyl group, an oxo group (═O), a thioxo group (═S), an imino group (═NH), a substituted imino group (═N—R³² in which R³² represents an aliphatic group, an aromatic group, or a heterocyclic group), an aliphatic group, an aromatic group, and a heterocyclic group.

L is preferably a single bond or a divalent linking group including an alkylene group or an oxyalkylene structure. The oxyalkylene structure is more preferably an oxyethylene structure or an oxypropylene structure. Further, L may include a polyoxyalkylene structure including two or more repeating oxyalkylene structures. The polyoxyalkylene structure is preferably a polyoxyethylene structure or a polyoxypropylene structure. The polyoxyethylene structure is represented by —(OCH CH₂)n-, and n is preferably an integer of 2 or more, and more preferably an integer of 2 to 10.

Examples of Z include an aliphatic group (for example, an alkyl group, a substituted alkyl group, an unsaturated alkyl group, and a substituted unsaturated alkyl group), an aromatic group (for example, an arylene group or a substituted arylene group), a heterocyclic group, an oxygen atom (—O—), a sulfur atom (—S—), an imino group (—NH—), a substituted imino group (—NR³¹— in which R³¹ represents an aliphatic group, an aromatic group, or a heterocyclic group), a carbonyl group (—CO—), and a combination thereof.

The aliphatic group may have a cyclic structure or a branched structure. The number of carbon atoms in the aliphatic group is preferably 1 to 20, more preferably 1 to 15, and still more preferably 1 to 10. Further, the aliphatic group includes a ring assembly hydrocarbon group or a crosslinked cyclic hydrocarbon ring. Examples of the ring assembly hydrocarbon groups include a bicyclohexyl group, a perhydronaphthalenyl group, a biphenyl group, and a 4-cyclohexyl phenyl group. Examples of the crosslinked cyclic hydrocarbon rings include a bicyclic hydrocarbon ring such as pinane, bornane, norpinane, norbornane, a bicyclooctane ring (a bicyclo[2.2.2]octane ring, a bicyclo[3.2.1]octane ring, and the like), a tricyclic hydrocarbon ring such as homobredane, adamantane, tricyclo[5.2.1.0^{2,6}]decane, a tricyclo[4.3.1.1^{2,5}]undecane ring, and a tetracyclic hydrocarbon ring such as tetracyclic[4.4.0.1^{2,5}.1^{7,10}]dodecane and perhydro-1,4-methano-5,8-methanonaphthalene rings. In addition, the crosslinked cyclic hydrocarbon rings include fused cyclic hydrocarbon rings which are a plurality of fused rings of 5- to 8-membered cycloalkane rings such as perhydronaphthalene (decalin), perhydroanthracene, perhydrophenanthrene, perhydroacenaphthene, perhydrofluorene, perhydroindene, and perhydrophenalene rings.

As the aliphatic group, a saturated aliphatic group is more preferable than an unsaturated aliphatic group. Further, the aliphatic group may have a substituent. Examples of the substituents include a halogen atom, an aromatic group, and a heterocyclic group. However, the aliphatic group has no acid group as the substituent.

The number of carbon atoms in the above-mentioned aromatic group is preferably 6 to 20, more preferably 6 to 15, and still more preferably 6 to 10. Further, the aromatic group may have a substituent. Examples of the substituents include a halogen atom, an aliphatic group, an aromatic group, and a heterocyclic group. However, the aromatic group has no acid group as the substituent.

The heterocyclic group preferably has a 5- or 6-membered ring as the heterocyclic ring. Another heterocyclic ring, aliphatic ring, or aromatic ring may be fused with the heterocyclic ring. The heterocyclic group may have a substituent. Examples of the substituents include a halogen atom, a hydroxyl group, an oxo group (═O), a thioxo group (═S), an imino group (═NH), a substituted imino group (═N—R³² in which R³² is an aliphatic group, an aromatic group, or a heterocyclic group), an aliphatic group, an aromatic group, and a heterocyclic group. However, the heterocyclic group has no acid group as the substituent.

In Formula (iii), R⁴, R⁵, and R⁶ each independently represent a hydrogen atom, a halogen atom (for example, fluorine, chlorine, and bromine), an alkyl group having 1 to 6 carbon atoms (for example, a methyl group, an ethyl group, and a propyl group), Z, or -L-Z. Here, L and Z have the same definitions as those defined above. As each of R⁴, R⁵, and R⁶, a hydrogen atom or an alkyl group having 1 to 3 carbon atoms is preferable, and a hydrogen atom is more preferable.

In the present invention, as the monomer represented by General Formula (i), a compound in which R¹, R², and R³ are each a hydrogen atom or a methyl group, L is a single bond, an alkylene group, or a divalent linking group including an oxyalkylene structure, X is an oxygen atom or an imino group, and Z is an aliphatic group, a heterocyclic group, or an aromatic group is preferable.

As the monomer represented by General Formula (ii), a compound in which R¹ is a hydrogen atom or a methyl group, L is an alkylene group, Z is an aliphatic group, a heterocyclic group, or an aromatic group, and Y is a methine group is preferable. Further, as the monomer represented by General Formula (iii), a compound in which R⁴, R⁵, and R⁶ are each a hydrogen atom or a methyl group, and Z is an aliphatic group, a heterocyclic group, or an aromatic group is preferable.

Examples of the typical compounds represented by Formulae (i) to (iii) include radically polymerizable compounds selected from acrylic acid esters, methacrylic acid esters, and styrenes.

In addition, with regard to the examples of the typical compounds represented by Formulae (i) to (iii), reference can be made to the compounds described in paragraphs 0089 to 0093 of JP2013-249417A, the contents of which are incorporated herein by reference.

In the polymer compound, the hydrophobic structural unit is preferably included in the amount in a range of 10% to 90%, and more preferably included in the amount in a range of 20% to 80%, in terms of mass, with respect to the total mass of the polymer compound. When the content is within the above range, sufficient pattern formation is achieved.

A functional group capable of interacting with a black pigment (in particular, titanium black) can be introduced into the polymer compound. Here, it is more preferable that the polymer compound has a structural unit having a functional group capable of interacting with the black pigment.

Examples of the functional group capable of interacting with the black pigment include an acid group, a basic group, a coordinating group, and a reactive functional group.

In a case where the polymer compound has the acid group, the basic group, the coordinating group, or the reactive functional group, it preferably has a structural unit having the acid group, a structural unit having the basic group, a structural unit having the coordinating group, or a structural unit having the reactivity, respectively.

In particular, by further having an alkali-soluble group such as a carboxyl group, as an acid group, the polymer compound is provided with developability for pattern formation through alkali development.

That is, by introducing the alkali-soluble group to the polymer compound, the polymer compound as a dispersant that is indispensable for the dispersion of the black pigment, in the composition of the present invention, has alkali-solubility. Such a composition containing the polymer compound is excellent in light-shielding properties in the exposure section, and improves alkali developability of an unexposed area.

In addition, by incorporating a structural unit having an acid group into the polymer compound, the polymer compound has an affinity for the solvent, so that the coating properties also tend to improve.

It is assumed that the acid group in the structural unit having the acid group is likely to interact with the black pigment, and the polymer compound disperses the black pigment stably. It is also assumed that the viscosity of the polymer compound that disperses the black pigment is reduced, so that the polymer compound itself is likely to be dispersed stably.

Meanwhile, the structural unit having the alkali-soluble group as the acid group may be the same as or different from the above-described structural unit having the graft chain. However, the structural unit having the alkali-soluble group as the acid group differs from the above-described hydrophobic structural unit (that is, the structural unit having the alkali-soluble group as the acid group does not correspond to the above-described hydrophobic structural unit).

Examples of the acid group which is a functional group capable of interacting with the black pigment include a carboxyl group, a sulfonic acid group, a phosphoric acid group, and a phenolic hydroxyl group. At least one of the carboxyl group, the sulfonic acid group, or the phosphoric acid group is preferable, and the carboxyl group is more preferable from the viewpoint that it has excellent adsorption force on the black pigment and high dispersibility for the black pigment.

That is, it is preferable that the polymer compound further has a structural unit having at least one of a carboxyl group, a sulfonic acid group, or a phosphoric acid group.

The polymer compound may have one kind or two or more kinds of structural units having an acid group.

The polymer compound may or may not contain a structural unit having an acid group. In a case where the polymer compound contains a structural unit having an acid group, the content of the structural unit having an acid group is preferably 5% to 80%, with respect to the total mass of the polymer compound, in terms of mass, and more preferably 10% to 60% from the viewpoint of suppressing a damage to image intensity caused by alkali development.

Examples of the basic group which is a functional group capable of interacting with the black pigment include a primary amino group, a secondary amino group, a tertiary amino group, a heterocyclic ring containing an N atom, and an amide group. The tertiary amino group is preferable from the viewpoint that it has excellent adsorption force on the black pigment and high dispersibility of the black pigment. The polymer compound may have one kind or two or more kinds of the basic groups.

The polymer compound may or may not contain a structural unit having a basic group. In a case where the polymer compound contains the structural unit having a basic group, the content of the structural unit having a basic group, in terms of mass, with respect to the total mass of the polymer compound, is preferably from 0.01% to 50%, and more preferably from 0.01% to 30% from the viewpoint of suppressing the development inhibition.

Examples of the coordinating group which is a functional group capable of interacting with the black pigment, and the reactive functional group include an acetylacetoxy group, a trialkoxysilyl group, an isocyanate group, an acid anhydride, and an acid chloride. The acetylacetoxy group is preferable from the viewpoint that it has excellent adsorption force on the black pigment and high dispersibility of the black pigment. The polymer compound may have one kind or two or more kinds of the groups.

The polymer compound may or may not contain a structural unit having a coordinating group or a structural unit having a reactive functional group. In a case where the polymer compound contains the structural unit having a coordinating group or the structural unit having a reactive functional group, the content of the structural unit, in terms of mass, with respect to the total mass of the polymer compound, is preferably from 10% to 80%, and more preferably from 20% to 60% from the viewpoint of suppressing the development inhibition.

In a case where the polymer compound in the present invention has a functional group capable of interacting with the black pigment other than the graft chain, the polymer compound may have the functional group capable of interacting with various black pigments, as described above. Further, how those functional groups are introduced is not particularly limited, but it is preferable that the polymer compound has at least one structural unit selected from the structural units derived from monomers represented by the following General Formulae (iv) to (vi).

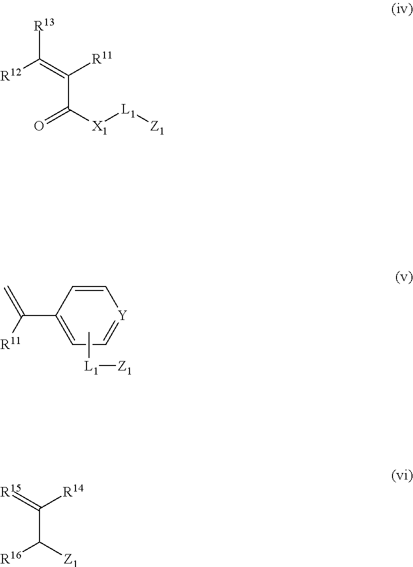

In General Formulae (iv) to (vi), R¹¹, R¹², and R¹³ each independently represent a hydrogen atom, a halogen atom (for example, a fluorine atom, a chlorine atom, and a bromine atom), or an alkyl group (for example, a methyl group, an ethyl group, and a propyl group) having 1 to 6 carbon atoms.

In General Formulae (iv) to (vi), it is more preferable that R¹¹, R¹², and R¹³ are each independently a hydrogen atom or an alkyl group having 1 to 3 carbon atoms, and it is still more preferable that R¹¹, R¹², and R¹³ are each independently a hydrogen atom or a methyl group. In General Formula (iv), it is particularly preferable that R¹² and R¹³ are each a hydrogen atom.

In General Formula (iv), X₁ represents an oxygen atom (—O—) or an imino group (—NH—), and is preferably an oxygen atom.

Furthermore, in General Formula (v), Y represents a methine group or a nitrogen atom.

Moreover, in General Formulae (iv) to (v), L₁ represents a single bond or a divalent linking group. Examples of the divalent linking groups include a divalent aliphatic group (for example, an alkylene group, a substituted alkylene group, an alkenylene group, a substituted alkenylene group, an alkynylene group, and a substituted alkynylene group), a divalent aromatic group (for example, an arylene group and a substituted arylene group), a divalent heterocyclic group, an oxygen atom (—O—), a sulfur atom (—S—), an imino group (—NH—), a substituted imino bond (—NR^{31′}— in which R^{31′} is an aliphatic group, an aromatic group, or a heterocyclic group), a carbonyl bond (—CO—), and a combination thereof.

The divalent aliphatic group may have a cyclic structure or a branched structure. The number of carbon atoms in the aliphatic group is preferably 1 to 20, more preferably 1 to 15, and still more preferably 1 to 10. As the aliphatic group, a saturated aliphatic group is more preferable than an unsaturated aliphatic group. The aliphatic group may have a substituent. Examples of the substituents include a halogen atom, a hydroxyl group, an aromatic group, and a heterocyclic group.

The number of carbon atoms in the above-mentioned divalent aromatic group is preferably 6 to 20, more preferably 6 to 15, and most preferably 6 to 10. The aromatic group may have a substituent. Examples of the substituents include a halogen atom, a hydroxyl group, an aliphatic group, an aromatic group, and a heterocyclic group.

The divalent heterocyclic group preferably has a 5- or 6-membered ring as the heterocyclic ring. One or more of another heterocyclic ring, aliphatic ring, or aromatic ring may be fused with the heterocyclic ring. The heterocyclic group may have a substituent. Examples of the substituents include a halogen atom, a hydroxyl group, an oxo group (═O), a thioxo group (═S), an imino group (═NH), a substituted imino group (═N—R³² in which R³² represents an aliphatic group, an aromatic group, or a heterocyclic group), an aliphatic group, an aromatic group, and a heterocyclic group.

It is preferable that L₁ is a single bond, an alkylene group, or a divalent linking group containing an oxyalkylene structure. It is more preferable that the oxyalkylene structure is an oxyethylene structure or an oxypropylene structure. Further, L₁ may include a polyoxyalkylene structure including two or more repeating oxyalkylene structures. As the polyoxyalkylene structure, a polyoxyethylene structure or a polyoxypropylene structure is preferable. The polyoxyethylene structure is represented by —(OCH₂CH₂)n- in which n is preferably an integer of 2 or more, and more preferably an integer of 2 to 10.

In General Formulae (iv) to (vi), Z₁ represents a functional group capable of interacting with the black pigment, other than the graft chain, and is preferably a carboxyl group or a tertiary amino group, and more preferably a carboxyl group.

In General Formula (vi), R¹⁴, R¹⁵, and R¹⁶ each independently represents a hydrogen atom, a halogen atom (for example, fluorine, chlorine, and bromine), an alkyl group having 1 to 6 carbon atoms (for example, a methyl group, an ethyl group, and a propyl group), —Z¹, or -L₁-Z₁. Here, L₁ and Z₁ have the same definitions as L₁ and Z₁ above, respectively, and the preferred examples thereof are also the same. It is preferable that R¹⁴, R¹⁵, and R¹⁶ each independently represent a hydrogen atom or an alkyl group having 1 to 3 carbon atoms, and more preferably a hydrogen atom.

In the present invention, as the monomer represented by General Formula (iv), a compound in which R¹¹, R¹², and R¹³ are each independently a hydrogen atom or a methyl group, L₁ is an alkylene group or a divalent linking group containing an oxyalkylene structure, X₁ is an oxygen atom or an imino group, and Z₁ is a carboxyl group is preferable.

Furthermore, as the monomer represented by General Formula (v), a compound in which R¹¹ is a hydrogen atom or a methyl group, L₁ is an alkylene group, Z₁ is a carboxyl group, and Y is a methine group is preferable.

In addition, as the monomer represented by General Formula (vi), a compound in which R¹⁴, R¹⁵, and R¹⁶ are each independently a hydrogen atom or a methyl group, and Z₁ is a carboxyl group is preferable.

Typical examples of the monomers (compounds) represented by General Formulae (iv) to (vi) are shown below.

Examples of the monomers include methacrylic acid, crotonic acid, isocrotonic acid, a reaction product of succinic anhydride and a compound (for example, 2-hydroxyethyl methacrylate) having an addition-polymerizable double bond and a hydroxyl group in the molecule, a reaction product of phthalic anhydride and a compound having an addition-polymerizable double bond and a hydroxyl group in the molecule, a reaction product of tetrahydroxy phthalic anhydride and a compound having an addition-polymerizable double bond and a hydroxyl group in the molecule, a reaction product of trimellitic anhydride and a compound having an addition-polymerizable double bond and a hydroxyl group in the molecule, a reaction product of pyromellitic anhydride and a compound having an addition-polymerizable double bond and a hydroxyl group in the molecule, an acrylic acid, an acrylic acid dimer, an acrylic acid oligomer, maleic acid, itaconic acid, fumaric acid, 4-vinylbenzoic acid, vinyl phenol, and 4-hydroxyphenyl methacrylamide.

From the viewpoints of the interaction with the black pigment, the dispersion stability, and the permeability of a developer, the content of the structural unit having a functional group capable of interacting with the black pigment is preferably 0.05% to 90% by mass, more preferably 1.0% to 80% by mass, and still more preferably 10% to 70% by mass, with respect to the total mass of the polymer compound.

Furthermore, for the purpose of improving various types of performance, such as image intensity, the polymer compound may further have other structural units (for example, a structural unit having a functional group with an affinity for a dispersion medium used for a dispersion) having various functions which differ from the structural unit with a graft chain, the hydrophobic structural unit, and the structural unit having a functional group capable of interacting with the black pigment as long as it does not impair the effects of the present invention.

Examples of other structural units include a structural unit derived from a radically polymerizable compound selected from acrylonitriles, methacrylonitriles, and the like.

The polymer compound may use one kind or two or more kinds of such other structural units. The content thereof is preferably from 0% to 80%, and more preferably from 10% to 60%, in terms of mass, with respect to the total mass of the polymer compound. When the content is within the range, sufficient pattern forming properties are maintained.

The acid value of the polymer compound is preferably in the range from 0 mgKOH/g to 160 mgKOH/g, more preferably in the range from 10 mgKOH/g to 140 mgKOH/g, and still more preferably in the range from 20 mgKOH/g to 120 mgKOH/g.

In a case where the acid value of the polymer compound is 160 mgKOH/g or less, the peeling of the pattern during the development at the time of forming the light-shielding film is more effectively inhibited. Further, when the acid value of the polymer compound is 10 mgKOH/g or more, the alkali developability is improved. In addition, when the acid value of the polymer compound is 20 mgKOH/g or more, precipitation of the black pigment (in particular, titanium black) or the dispersoid including the titanium black and Si atoms can further be suppressed, the number of coarse particles can further be reduced, and the temporal stability of the composition can further be improved.

In the present invention, the acid value of the polymer compound is calculated from the average content of the acid groups in the polymer compound, for example. Further, a resin having a desired acid value is obtained by changing the content of a structural unit containing an acid group, which is a constituent of the polymer compound.

At the time of forming the light-shielding film, the weight-average molecular weight of the polymer compound in the present invention is preferably from 4,000 to 300,000, more preferably from 5,000 to 200,000, still more preferably from 6,000 to 100,000, and particularly preferably from 10,000 to 50,000, as a value in terms of polystyrene measured by a gel permeation chromatography (GPC) method, from the viewpoint of suppressing the peeling of the pattern during the development and the developability.

The GPC method uses HLC-8020GPC (manufactured by Tosoh Corporation), and is based on a method using TSKgel SuperHZM-H, TSKgel SuperHZ4000, or TSKgel SuperHZ2000 (manufactured by Tosoh Corporation, 4.6 mmID×15 cm) as a column and tetrahydrofuran (THF) as an eluent.

The polymer compound is synthesized based on a known method. Examples of solvents used for synthesizing the polymer compound include ethylene dichloride, cyclohexanone, methyl ethyl ketone, acetone, methanol, ethanol, propanol, butanol, ethylene glycol monomethyl ether, ethylene glycol monoethyl ether, 2-methoxyethyl acetate, 1-methoxy-2-propanol, 1-methoxy-2-propyl acetate, N,N-dimethylformamide, N,N-dimethylacetamide, dimethyl sulfoxide, toluene, ethyl acetate, methyl lactate, and ethyl lactate. These solvents may be used singly or as a mixture of two or more kinds thereof.

Specific examples of the polymer compounds which can be used in the present invention include “Disperbyk-161, 162, 163, 164, 165, 166, 170, and 190 (trade names, polymeric copolymers)” manufactured by BYK-Chemie GmbH, “EFKA 4047, 4050, 4010, and 4165 (trade names, polyurethane-based), and EFKA 4330 and 4340 (trade names, block copolymers)” manufactured by EFKA.

These polymer compounds may be used singly or in combination of two or more kinds thereof.

Furthermore, with regard to specific examples of the polymer compound, reference can be made to the polymer compounds described in paragraphs 0127 to 0129 of JP2013-249417A, the contents of which are incorporated herein by reference.

Moreover, as the dispersant, in addition to the above-mentioned polymer compounds, the graft copolymers in paragraphs 0037 to 0115 of JP2010-106268A (the sections of paragraphs 0075 to 0133 of the corresponding US2011/0124824A) can be used, the contents of which can be cited and incorporated herein by reference.

Furthermore, in addition to the above, the polymer compounds in paragraphs 0028 to 0084 of JP2011-153283A (the sections of paragraphs 0075 to 0133 of the corresponding US2011/0279759A), including constituents having a side chain structure formed by the bonding of acidic groups via a linking group, can be used, the contents of which can be cited and incorporated herein by reference.

The content of the dispersant in the composition of the present invention is preferably 0.1% to 50% by mass, and more preferably 0.5% to 30% by mass, with respect to the total solid content of the composition.

(Binder Polymer)

The composition of the present invention may further contain a binder polymer.

A linear organic polymer is preferably used as the binder polymer. Any known linear organic polymer may be used arbitrarily as the linear organic polymer. Preferably, a linear organic polymer which is soluble or swellable in water or weakly alkaline water is chosen so as to allow water development or weakly alkaline water development. Among those, an alkali-soluble resin (resin having a group enhancing alkali-solubility) is particularly preferable as the binder polymer.

The binder polymer may be a linear organic high-molecular-weight polymer, and can be appropriately selected from alkali-soluble resins having at least one group enhancing alkali-solubility in a molecule (preferably a molecule having an acrylic copolymer or a styrene-based copolymer as a main chain). From the viewpoint of heat resistance, a polyhydroxystyrene-based resin, a polysiloxane-based resin, an acrylic resin, an acrylamide-based resin, and an acryl/acrylamide copolymer resin are preferable, and further, from the viewpoint of controlling developability, an acrylic resin, an acrylamide-based resin, and an acryl/acrylamide copolymer resin are preferable.

Examples of the group enhancing alkali-solubility (hereinafter also referred to as an acid group) include a carboxyl group, a phosphoric acid group, a sulfonic acid group, and a phenolic hydroxyl group, and is preferably a group which is soluble in an organic solvent and can be developed by an aqueous weak alkaline solution, and more preferably a carboxyl group. Preferred examples of such a repeating unit having the carboxyl group include repeating units derived from the (meth)acrylic acid. These acid groups may be used singly or in combination of two or more kinds thereof.

Examples of the binder polymer include radical polymers having a carboxyl group in the side chain, for example, those described in JP1984-44615A (JP-S59-44615A), JP1979-34327B (JP-S54-34327B), JP1983-12577B (JP-S58-12577B), and JP1979-25957B (JP-S54-25957B), JP1979-92723A (JP-S54-92723A), JP1984-53836A (JP-S59-53836A), and JP1984-71048A (JP-S59-71048A), that is, a resin obtained by homopolymerizing or copolymerizing a monomer having a carboxyl group; a resin obtained by homopolymerizing or copolymerizing a monomer having an acid anhydride, and subjecting the acid anhydride unit to hydrolysis, semi-esterification or semi-amidation; and an epoxy acrylate obtained by modifying an epoxy resin with an unsaturated monocarboxylic acid and an acid anhydride. Examples of the monomers having a carboxyl group include acrylic acid, methacrylic acid, itaconic acid, crotonic acid, maleic acid, fumaric acid, and 4-carboxylstyrene, and examples of the monomers having an acid anhydride include maleic anhydride. Further, similarly, other examples thereof include an acidic cellulose derivative having a carboxyl group in a side chain. In addition, an addition reaction product of a polymer having a hydroxyl group with a cyclic acid anhydride, and the like are useful.

Moreover, the acetal-modified polyvinyl alcohol-based binder polymers having an acid group as described in each publication of EP993966B, EP1204000B, JP2001-318463A, and the like are excellent in a balance between the film hardness and the developability, which is thus suitable.

In addition, polyvinyl pyrrolidone, polyethylene oxide and the like are also useful as the water-soluble linear organic polymer. In order to increase the strength of the cured coating film, alcohol-soluble nylon, polyether which is a reaction product from 2,2-bis-(4-hydroxyphenyl)-propane and epichlorohydrin, and the like are also useful.

In particular, among those, a copolymer of [benzyl (meth)acrylate/(meth)acrylic acid/other optional addition-polymerizable vinyl monomers] and a copolymer of [allyl (meth)acrylate/(meth)acrylic acid/and other option addition-polymerizable vinyl monomers] are suitable in that they are excellent in a balance among the film hardness, the sensitivity, and the developability.

Examples of the commercially available products thereof include ACRYLBASE FF-187 and FF-426 (manufactured by Fujikura Kasei Co., Ltd.), ACRYCURE RD-F8 (manufactured by Nippon Shokubai Co., Ltd.), and CYCLOMER P ACA 230AA (manufactured by DAICEL-ALLNEX LTD).

In addition, the binder polymer may include the above-mentioned structural unit with a graft chain (the structural unit represented by any one of Formulae (1) to (4)).

For the production of the binder polymer, for example, a method implemented by a known radical polymerization method can be applied. Polymerization conditions such as a temperature, a pressure, the type and amount of a radical initiator, and the type of a solvent, and the like at the time of producing the alkali-soluble resin by a radical polymerization method can be easily set by those skilled in the art, and the conditions can also be determined experimentally.

The content of the binder polymer in the composition of the present invention is preferably 0.1% to 30% by mass, and more preferably 0.3% to 25% by mass, with respect to the total solid content of the composition.

<Solvent>

The composition of the present invention may also contain a solvent.

Examples of the solvent include water and an organic solvent.

Examples of the organic solvents include, but not limited to, acetone, methyl ethyl ketone, cyclohexane, ethyl acetate, ethylene dichloride, tetrahydrofuran, toluene, ethylene glycol monomethyl ether, ethylene glycol monoethyl ether, ethylene glycol dimethyl ether, propylene glycol monomethyl ether, propylene glycol monoethyl ether, acetylacetone, cyclohexanone, cyclopentanone, diacetone alcohol, ethylene glycol monomethyl ether acetate, ethylene glycol ethyl ether acetate, ethylene glycol monoisopropyl ether, ethylene glycol monobutyl ether acetate, 3-methoxypropanol, methoxymethoxyethanol, diethylene glycol monomethyl ether, diethylene glycol monoethyl ether, diethylene glycol dimethyl ether, diethylene glycol diethyl ether, propylene glycol monomethyl ether acetate, propylene glycol monoethyl ether acetate, 3-methoxypropyl acetate, N,N-dimethylformamide, dimethylsulfoxide, γ-butryrolactone, butyl acetate, methyl lactate, and ethyl lactate.

The solvents may be used singly or in combination of two or more kinds thereof.

In a case of using the solvents in combination of two or more kinds thereof, it is particularly preferable that the solvents are composed of two or more selected from the group consisting, of methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclopentanone, ethyl carbitol acetate, butyl carbitol acetate, propylene glycol methyl ether, and propylene glycol methyl ether acetate.

The amount of the solvent to be included in the composition is preferably 10% to 90% by mass, and more preferably 20% to 85% by mass, with respect to the total mass of the composition.

<Other Components>

The composition of the present invention may also include an ultraviolet absorbent. Thus, the shape of the pattern can become more excellent (finer).

As the ultraviolet absorbent, ultraviolet absorbents such as salicylate-based, benzophenone-based, benzotriazole-based, substituted acrylonitrile-based, and triazine-based ultraviolet absorbents can be used. As for specific examples thereof, the compounds in paragraphs 0137 to 0142 of JP2012-068418A (paragraphs 0251 to 0254 of the corresponding US2012/0068292A) can be used, the contents of which can be cited and incorporated herein by reference.

In addition to those, a diethylamino-phenylsulfonyl-based ultraviolet absorbent (trade name: UV-503, manufactured by Daito Chemical Co., Ltd.), or the like is suitably used.

Examples of the ultraviolet absorbent include the compounds exemplified in paragraphs 0134 to 0148 of JP2012-32556A.

The composition may or may not include the ultraviolet absorbent, but in a case where the composition includes the ultraviolet absorbent, the content of the ultraviolet absorbent is preferably 0.001% to 15% by mass, more preferably 0.01% to 10% by mass, and still more preferably 0.1% to 5% by mass, with respect to the total solid content of the composition.

From the viewpoint of further improving the coating properties, various surfactants may be added to the composition. As the surfactant, various surfactants such as a fluorine-based surfactant, a non-ionic surfactant, a cationic surfactant, an anionic surfactant, and a silicone-based surfactant can be used. Further, these surfactants are different from the above-mentioned curable compounds. In particular, the composition of the present invention can further improve the uniformity of the thickness or liquid saving properties in that the liquid characteristics (in particular, fluidity) are improved due to incorporation of a fluorine-based surfactant into the composition.

Examples of the fluorine-based surfactant include MEGAFACE F171, MEGAFACE F172, MEGAFACE F173, MEGAFACE F176, MEGAFACE F177, MEGAFACE F141, MEGAFACE F142, MEGAFACE F143, MEGAFACE F144, MEGAFACE R30, MEGAFACE F437, MEGAFACE F475, MEGAFACE F479, MEGAFACE F482, MEGAFACE F554, MEGAFACE F780, and MEGAFACE F781F (all manufactured by DIC Corporation); FLUORAD FC430, FC431, and FC171 (all manufactured by Sumitomo 3M); and SURFLON S-382, SURFLON SC-101, SURFLON SC-103, SURFLON SC-104, SURFLON SC-105, SURFLON SC-1068, SURFLON SC-381, SURFLON SC-383, SURFLON S-393, and SURFLON KH-40 (all manufactured by Asahi Glass Co., Ltd.).

Specific examples of other surfactants include the surfactants described in paragraphs 0174 to 0177 of JP2013-249417A, the contents of which are incorporated herein by reference.

The surfactants may be used singly or in combination of two or more kinds thereof.

The amount of the surfactant to be added is preferably 0.001% to 2.0% by mass, and more preferably 0.005% to 1.0% by mass, with respect to the total mass of the composition.

Furthermore, a fluorine-containing polymer having an ethylenically unsaturated group in a side chain can also be used as the fluorine-based surfactant. Specific examples thereof include the compounds described in paragraphs 0050 to 0090 and paragraphs 0289 to 0295 of JP2010-164965A, such as MEGAFACE RS-101, RS-102, and RS-718K, all manufactured by DIC Corporation.

In addition to the components, the following components may further be added to the composition. For example, a sensitizer, a co-sensitizer, a crosslinking agent, a curing accelerator, a filler, a thermal curing accelerator, a polymerization inhibitor, a plasticizer, a diluent, and an oleophilizing agent, and known additives such as an adhesion accelerator onto a substrate surface and other preparations (for example, electrically conductive particles, a filler, an antifoaming agent, a flame retardant, a leveling agent, a peeling accelerator, an antioxidant, a perfume, a surface tension adjuster, and a chain transfer agent) may also be added, as desired.

With regard to these components, reference can be made to, for example, the descriptions in paragraphs 0183 to 0228 of JP2012-003225A ([0237] to [0309] of the corresponding US2013/0034812A), paragraphs 0101 to 0102, paragraphs 0103 to 0104, and paragraphs 0107 to 0109 of JP2008-250074A, paragraphs 0159 to 0184 of JP2013-195480A, and the like, the contents of which are incorporated herein by reference.

The concentration of the solid content of the composition of the present invention is preferably 5% to 50% by mass, and more preferably 15% to 40% by mass from the viewpoint of a balance between the thickness and the light-shielding properties of the light-shielding film to be formed.

<Method for Preparing Composition>

The composition of the present invention can be prepared by mixing the above-mentioned various components using a known mixing method (for example, a stirrer, a homogenizer, a high-pressure emulsifier, a wet-grinder, and a wet dispersing machine).

The composition of the present invention is preferably filtered by a filter for the purposes such as removal of a foreign substance and reduction in defects. The filter is used with no particular limitation as long as it is the one which has been used for filtration or the like in the related art. Examples of the filter include those made of a fluorocarbon resin such as polytetrafluoroethylene (PTFE); a polyamide resin such as nylon; and a polyolefin resin (including high-density and ultra-high-molecular-weight polyolefin resins) such as polyethylene and polypropylene (PP). Among these materials, polypropylene (including high-density polypropylene) and nylon are preferable.

The pore diameter of the filter is suitably approximately 0.1 to 7.0 preferably approximately 0.2 to 2.5 μm, more preferably approximately 0.2 to 1.5 μm, and still more preferably 0.3 to 0.7 μm. Within the above range, fine foreign substances such as impurities, aggregates, and the like included in the pigment can be reliably reduced while suppressing the filtration clogging of the pigment.

When a filter is used, other filters may be combined. At that time, filtering at a first filter may be performed once or two or more times. When other filters are combined to perform filtering two or more times, it is preferable that a pore diameter at a filtering after a second filtering is larger than a pore diameter at a first filtering. In addition, first filters having different pore diameters within the above-mentioned range may be combined. As the pore diameter herein, reference may be made to nominal values of a filter maker. A commercially available filter may be selected from various filters provided by, for example, Pall Corporation, Advantec Toyo Kaisha, Ltd., Nihon Entegris K. K. (formerly Nippon Microlith Co., Ltd.), Kitz Micro Filter Corporation, or the like.

As a second filter, a filter formed of a material which is the same as the material for the above-mentioned first filter and the like can be used. The pore diameter of the second filter is suitably approximately 0.2 to 10.0 μm, preferably approximately 0.2 to 7.0 μm, and more preferably approximately 0.3 to 6.0 μm.

<Light-Shielding Film and Method for Producing the Same>

It is possible to form a light-shielding film by using the above-mentioned composition.

The light-shielding film thus formed has a bilayer structure with a black layer (under layer) including the black pigment and a coating layer (upper layer) formed of a curable compound, as described in FIG. 1 above. Further, the coating layer is usually a layer disposed on the side (air side) opposite to the substrate in the light-shielding film disposed on the substrate.

The black layer usually includes the above-mentioned black pigment.

The coating layer is a layer formed of a curable compound which is unevenly distributed in the vicinity of the surface of the coating film obtained by applying the composition. Further, in the coating, layer, a curable functional group in the curable compound may also be reacted. In addition, the coating layer does not include the black pigment.

The refractive index of the coating layer is preferably lower than the refractive index of the black layer.

The thickness of the light-shielding film is not particularly limited, and from the viewpoint that the effects of the present invention are more excellent, the thickness is preferably 0.2 to 25 μm, and more preferably 1.0 to 10 μm.

The thickness is an average thickness, which is a value obtained by measuring the thickness at arbitrary 5 or more points of the light-shielding film, and arithmetically averaging the values.

The method for producing the light-shielding film is not particularly limited, and examples thereof include a method in which the above-mentioned composition is applied onto a substrate to form a coating film, and the coating film is subjected to a curing treatment to produce a light-shielding film.

The method for the curing treatment is not particularly limited, but examples thereof include a photocuring treatment and a thermal curing treatment, and from the viewpoint of easiness of pattern formation, the photocuring treatment (in particular, an ultraviolet irradiation treatment) is preferable.

Furthermore, the type of a substrate to be used is not particularly limited, and preferred examples thereof include various members (for example, an infrared cut filter, an outer peripheral portion of a solid-state imaging element, an outer peripheral portion of a wafer level lens, and a backside of a solid-state imaging element) in a solid-state imaging device.

Examples of the suitable aspect in a case of producing a light-shielding film in the pattern shape include an aspect including a step of applying the composition of the present invention onto a substrate to form a composition layer (hereinafter simply referred to as a “composition layer forming step”), a step of exposing the composition layer through a mask (hereinafter simply referred to as an “exposing step”), and a step of developing the composition layer after the exposure to form a light-shielding film (light-shielding film in the pattern shape) (hereinafter simply referred to as a “developing step”).

Specifically, a light-shielding film in the pattern shape can be produced by applying the composition of the present invention onto a substrate directly or through another layer to form a composition layer (composition layer forming step), exposing the composition layer through a predetermined mask pattern to cure only the composition layer portion irradiated with light (exposing step), and performing development using a developer (developing step).

Hereinafter, the respective steps in the aspect will be described.

[Composition Layer Forming Step]

In the composition layer forming step, the composition of the present invention is applied onto a substrate to form a composition layer.

Examples of the substrate include various members (for example, an infrared cut filter, an outer peripheral portion of a solid-state imaging element, an outer peripheral portion of a wafer level lens, and a backside of a solid-state imaging element) in a solid-state imaging device.

As a method for applying the composition of the present invention on the substrate, various application methods such as slit coating, an ink jet method, spin coating, cast coating, roll coating, and a screen printing method can be applied.

The composition applied to the substrate is usually dried under the conditions of a temperature of from 70° C. to 110° C. for a period from approximately 2 minutes to 4 minutes to form a composition layer.

[Exposing Step]

In the exposing step, the composition layer formed in the composition layer forming step is exposed through a mask to cure only the composition layer portion irradiated with light.

The exposure is preferably performed by the irradiation with radiation, and as the radiation that can be used at the time of performing the exposure, in particular, ultraviolet rays such as g-rays, h-rays, and i-rays are preferably used. The high-pressure mercury lamp is more preferred as the light source. The irradiation intensity is preferably from 5 mJ/cm² to 1,500 mJ/cm², and more preferably from 10 mJ/cm² to 1000 mJ/cm².

[Developing Step]

Following the exposing step, a developing treatment (developing step) is performed to elute a portion not irradiated with light in the exposing step into a developer (for example, an aqueous alkaline solution), and as a result, only a photocured portion remains.

As a developer, an organic alkaline developer is preferable. The development temperature is usually from 20° C. to 30° C., and the development time is from 20 seconds to 90 seconds.

As for the aqueous alkaline solution, examples of the inorganic developer include sodium hydroxide, potassium hydroxide, sodium carbonate, sodium hydrogen carbonate, sodium silicate, and sodium metasilicate, and examples of the organic alkaline developer include an aqueous alkaline solution obtained by dissolving an alkali compound such as aqueous ammonia, ethylamine, diethylamine, dimethylethanolamine, tetramethylammonium hydroxide, tetraethylammonium hydroxide, tetrapropylammonium hydroxide, tetrabutylammonium hydroxide, benzyltrimethylammonium hydroxide, choline, pyrrole, piperidine, and 1,8-diazabicyclo-[5,4,0]-7-ubdecene to a concentration of 0.001% to 10% by mass, and preferably 0.005% to 0.5% by mass. For example, a suitable amount of a water-soluble organic solvent such as methanol and ethanol and/or a surfactant, or the like can also be added to the aqueous alkaline solution. Further, in a case where a developer formed of such an aqueous alkaline solution is used, the pattern is generally washed (rinsed) with pure water after development.

In addition, after performing the composition layer forming step, the exposing step, and the developing step, a curing step of curing the formed light-shielding film in the pattern shape by heating and/or exposure may also be carried out, if desired.

<Infrared Cut Filter with Light-Shielding Film and Solid-State Imaging Device>

The above-mentioned light-shielding film can be suitably applied to a solid-state imaging device.

Hereinafter, first, a first embodiment of the solid-state imaging device having the light-shielding film of the present invention will be described in detail.

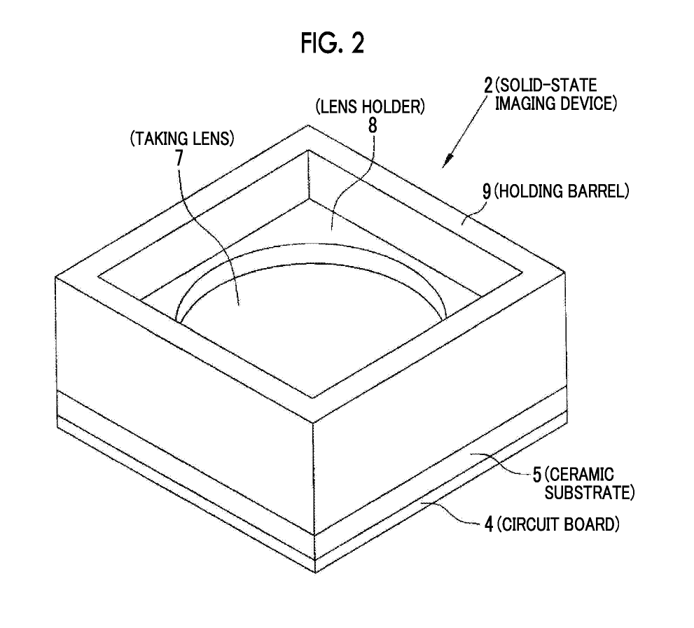

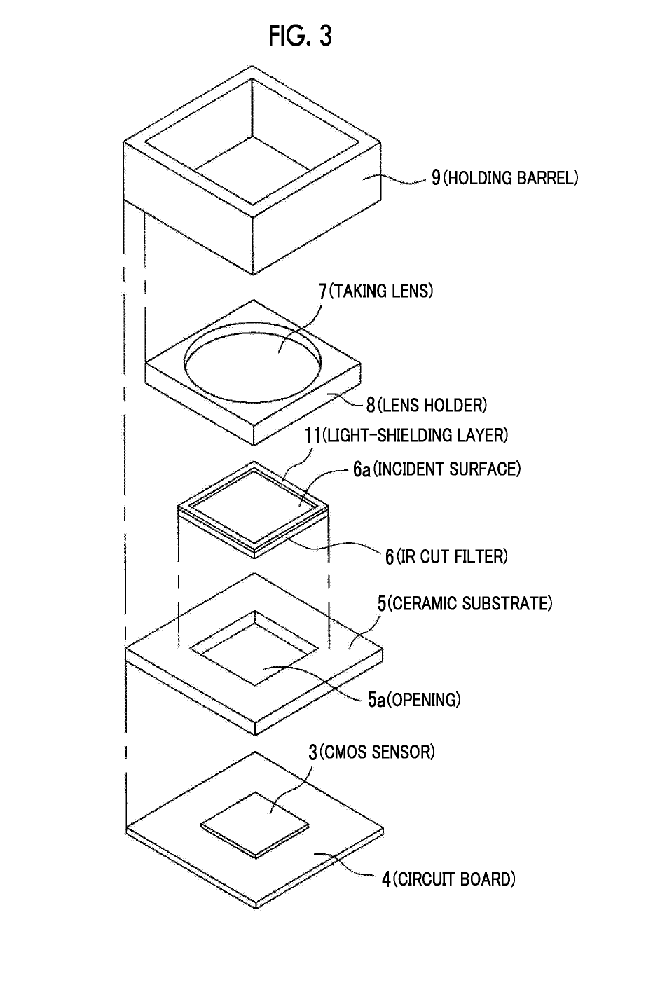

As shown in FIGS. 2 and 3, a solid-state imaging device 2 includes a CMOS sensor 3 as a solid-state imaging element, a circuit board 4 on which the CMOS sensor 3 is mounted and a ceramic substrate 5 made of ceramic, which supports the circuit board 4. Further, the solid-state imaging device 2 includes an IR cut filter 6 which is supported by the ceramic substrate 5 and cuts infrared light (IR) traveling toward the CMOS sensor 3, a taking lens 7, a lens holder 8 which holds the taking lens 7, and a holding barrel 9 which holds the lens holder 8 in a movable manner. In addition, a CCD sensor or an organic CMOS sensor may also be provided instead of the CMOS sensor 3.

The ceramic substrate 5 has the shape of a frame formed with an opening 5a to which the CMOS sensor 3 is inserted, and surrounds the sides of the CMOS sensor 3. In this state, the circuit board 4 on which the CMOS sensor 3 is mounted is fixed to the ceramic substrate 5 with an adhesive (for example, an epoxy-based adhesive, the same hereinafter). Various circuit patterns are formed in the circuit board 4.

The IR cut filter 6 has a reflective film which reflects infrared light on a plate-shaped glass or a blue glass, and the surface on which the reflective film is formed becomes an incident surface 6a. The IR cut filter 6 is formed with a size slightly greater than that of the opening 5a and fixed to the ceramic substrate 5 with the adhesive so as to cover the opening 5a.

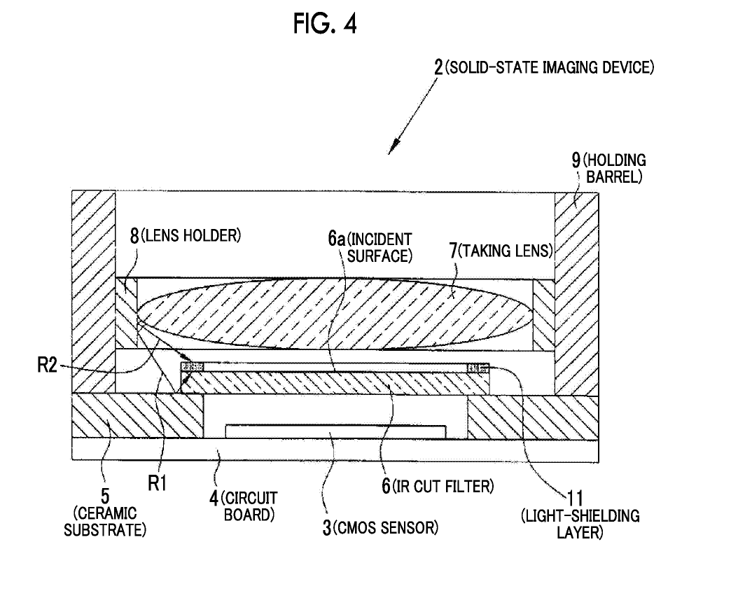

The CMOS sensor 3 is disposed behind (in a lower portion in FIGS. 3 and 4) of the taking lens 7, and the IR cut filter 6 is disposed between the taking lens 7 and the CMOS sensor 3. The subject light is incident on a light receiving surface of the CMOS sensor 3 through the taking lens 7 and the IR cut filter 6. At this time, the infrared light is cut by the IR cut filter 6.

The circuit board 4 is connected to a control unit provided in an electronic machine (for example, a digital camera) in which the solid-state imaging device 2 is loaded, and power is supplied from the electronic machine to solid-state imaging device 2. A plurality of color pixels are arranged in two dimensions in the light receiving surface of the CMOS sensor 3, and each color pixel photoelectrically converts the incidence ray and stores a signal charge generated.

As shown in FIGS. 3 and 4, in the edge of the incident surface 6a of the IR cut filter 6, the light-shielding film (light-shielding layer) 11 is disposed around the entire periphery and an infrared cut filter with a light-shielding film is formed. In a case where reflected light R1 which is emitted from the taking lens 7 and reflected on the entire surface (the upper surface in FIGS. 3 and 4) of the ceramic substrate 5 is incident on the CMOS sensor 3 after being repeatedly reflected and refracted in the device, or a case where reflected light R2 which is emitted from the taking lens 7 and reflected on the inner wall of the lens holder 8 is incident on the CMOS sensor 3, the occurrence of flare is caused in the taken image. The light-shielding film 11 shields harmful light such as reflected light R1 and R2 toward the CMOS sensor 3. The light-shielding film 11 is applied by a spin coating method for a spray coating method, for example. In addition, the thickness of the light-shielding film 11 is drawn with exaggeration in FIGS. 3 and 4.

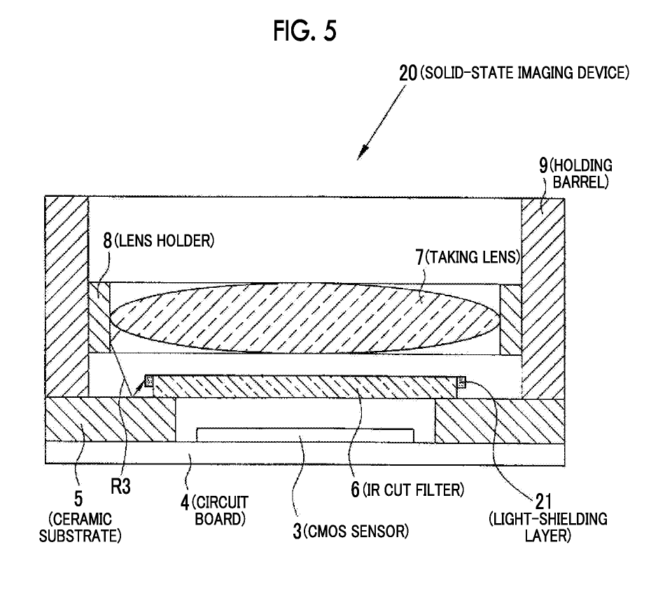

The solid-state imaging device 20 of the second embodiment is shown in FIG. 5. Further, the same constituent members as those in the first embodiment will be attached with the same symbols, with the detailed descriptions thereof being omitted.

The solid-state imaging device 20 includes the CMOS sensor 3, the circuit board 4, the ceramic substrate 5, the IR cut filter 6, the taking lens 7, the lens holder 8, and the holding barrel 9. The above-mentioned light-shielding film (light-shielding layer) 21 is disposed around the entire periphery on the side end surface of the IR cut filter 6. In a case where reflected light R3 which is emitted from the taking lens 7 and reflected on the entire surface of the ceramic substrate 5 is incident on the CMOS sensor 3 after being repeatedly reflected and refracted in the device, the occurrence of flare is caused in the taken image. The light-shielding film 21 shields harmful light such as reflected light R3 toward the CMOS sensor 3.

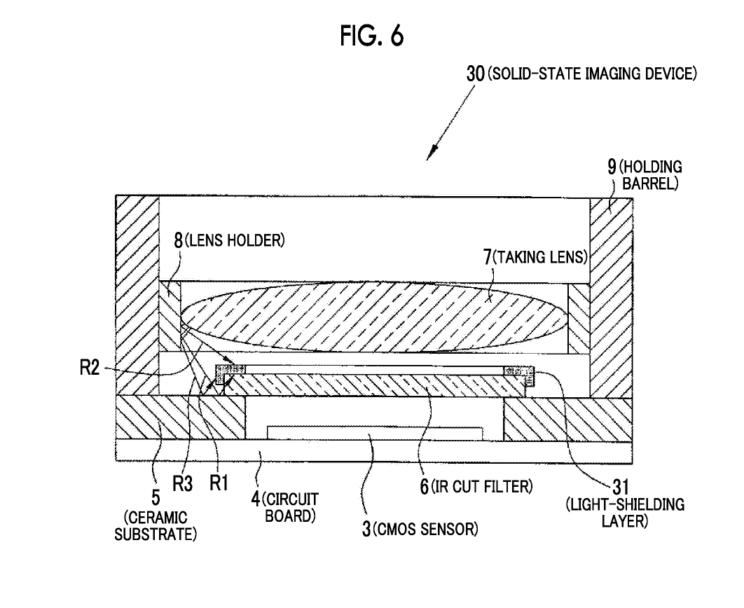

The solid-state imaging device 30 of the third embodiment is shown in FIG. 6. Further, the same constituent members as those in the first embodiment will be attached with the same symbols, with the detailed descriptions thereof being omitted.

The solid-state imaging device 30 includes the CMOS sensor 3, the circuit board 4, the ceramic substrate 5, the IR cut filter 6, the taking lens 7, the lens holder 8, and the holding barrel 9. The above-mentioned light-shielding film (light-shielding layer) 31 is disposed around the entire periphery on the edge and the side end surface of the incident surface 6a of the IR cut filter 6. That is, first, the second embodiment may also be combined therewith. In this embodiment, first, the light-shielding performance is enhanced, as compared with that in the second embodiment, and therefore, the occurrence of flare is reliably suppressed.

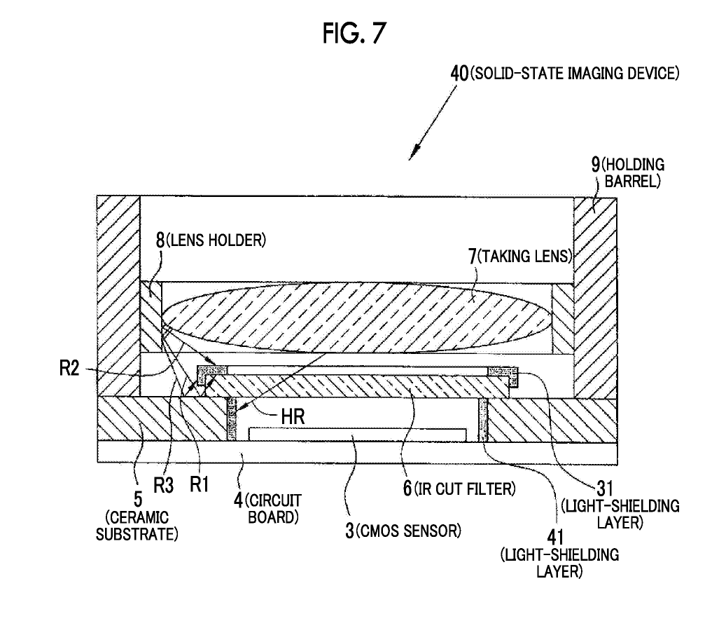

The solid-state imaging device 40 of the fourth embodiment is shown in FIG. 7. Further, the same constituent members as those in the first embodiment will be attached with the same symbols, with the detailed descriptions thereof being omitted.

The solid-state imaging device 40 includes the CMOS sensor 3, the circuit board 4, the ceramic substrate 5, the IR cut filter 6, the taking lens 7, the lens holder 8, and the holding barrel 9. The above-mentioned light-shielding film (light-shielding layer) 31 is disposed around the entire periphery on the edge and the side end surface of the incident surface 6a of the IR cut filter 6.

Furthermore, the light-shielding film (light-shielding layer) 41 is formed on the inner wall of the ceramic substrate 5. In a case where reflected light which is emitted from the taking lens 7, passes through the IR cut filter 6, and is reflected on the inner wall of the ceramic substrate 5 is incident on the CMOS sensor 3, the occurrence of flare is caused in the taken image. In this light-shielding film 41, the light-shielding performance is enhanced, as compared with the inner wall of the ceramic substrate 5, and therefore, the occurrence of flare is reliably suppressed.

### EXAMPLES

Hereinafter, the present invention will be described in more details, but the present invention is not limited to the following Examples unless it does not exceed the gist thereof. Further, unless otherwise specified, “parts” and “%” are in terms of mass. In addition, the room temperature refers to 25° C.

Moreover, with regard to the present Examples, for each of the time after the preparation of the dispersion which will be described later and the time after the preparation of the composition which will be described later, filtration was performed using a DFA4201NXEY (0.45-μm nylon filter).

<Manufacture of Titanium Black (A-1)>

120 g of titanium oxide TTO-51N (trade name, manufactured by Ishihara Sangyo Kaisha Ltd.) having a BET specific surface area of 110 m²/g, 25 g of silica particles, AEROSIL 300 (registered trademark) 300/30 (manufactured by Evonik Corporation) having a BET specific surface area of 300 m²/g, and 100 g of a dispersant, Disperbyk 190 (trade name, manufactured by BYK Japan KK), were weighed. 71 g of ion-exchanged water was added thereto, and the mixture was treated for 30 minutes at a revolution rotation speed of 1,360 rpm and a spinning rotation speed of 1,047 rpm, using MAZERSTAR KK-400 W manufactured by KURABO, thereby obtaining a uniform aqueous solution. The aqueous solution was filled into a quartz vessel and heated at 920° C. in an oxygen atmosphere, using a compact size rotary kiln (manufactured by K.K. MOTOYAMA). Then, the mixture was subjected to a nitridization reduction treatment by replacing the atmosphere with nitrogen and then flowing ammonia gas thereinto at the same temperature at the rate of 100 mL/min for 5 hours. After the completion of the treatment, recovered powder was pulverized in a mortar to obtain a titanium black (A-1) [dispersoid including titanium black particles and Si atoms] containing Si atoms and having a specific surface area of 85 m²/g in the powder shape.

<Preparation of Titanium Black Dispersion (TB Dispersion Liquid 1)>

The components shown in the following composition 1 were mixed for 15 minutes, using a stirrer (EUROSTAR manufactured by IKA) to obtain a dispersion a.

In addition, the specific resin 1 described below was synthesized with reference to the description in JP2013-249417A. In the formulae of the specific resin 1, x was 43% by mass, y was 49% by mass, and z was 8% by mass. Further, the specific resin 1 had a weight-average molecular weight of 30,000, an acid value of 60 mgKOH/g, and the number of atoms in the graft chain (excluding hydrogen atoms) was 117.

(Composition 1)
Titanium black (A-1) obtained as described above . . . 25 parts by mass
30%-by-mass solution of propylene glycol monomethyl ether acetate of specific resin 1 . . . 25 parts by mass
Propylene glycol monomethyl ether acetate (PGMEA) (solvent) . . . 50 parts by mass

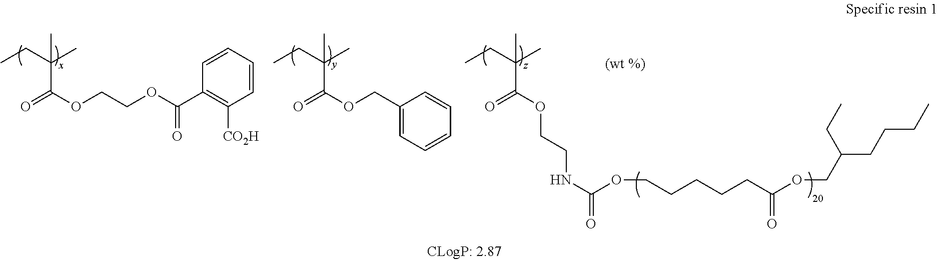

The obtained dispersion a was subjected to a dispersion treatment using an ULTRA APEX MILL UAM015 manufactured by Kotobuki Industries Co., Ltd. under the following conditions to obtain a titanium black dispersion (hereinafter denoted as TB dispersion liquid 1).

(Dispersion Conditions)
Bead diameter: φ0.05 mm
Beads filling rate: 75% by volume
Circumferential speed of mill: 8 m/sec
Amount of mixed liquid to be subjected to a dispersion treatment: 500 g
Circulation flow rate (pump supply amount): 13 kg/hour
Temperature of treatment liquid: 25° C. to 30° C.
Cooling water: tap water
Inner volume of circular path of beads mill: 0.15 L
Number of passes: 90 passes

(Synthesis of Specific Resin 2)

According to the production method in paragraphs 0338 to 0340 of JP2010-106268A, a specific resin 2 was obtained. Further, in the formula of the specific resin 2, x was 90% by mass, y was 0% by mass, and z was 10% by mass. Further, the specific resin 2 had a weight-average molecular weight of 40,000, an acid value of 100 mgKOH/g, and the number of atoms in the graft chain (excluding hydrogen atoms) was 117.

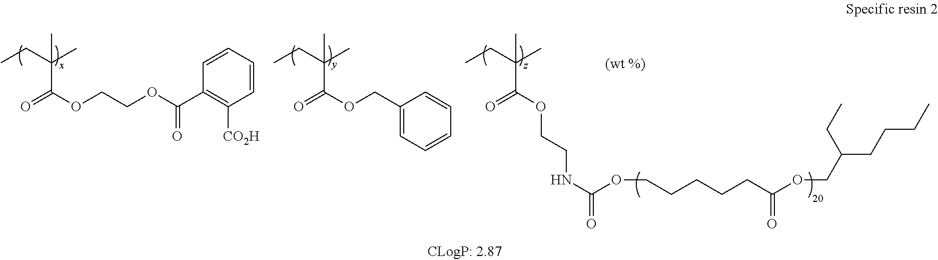

### Synthesis Example: Synthesis of Fluorine-Containing Resin 1

The fluorine-containing resin 1 can be synthesized through the two steps shown below.

(Step 1: Synthesis of Fluorine-Containing Resin 1a)

—Composition 1—
i6FMA <1,1,1,3,3,3-hexafluoroisopropyl methacrylate> 5.98 g
2-Hydroxyethyl methacrylate [monomer] 5.98 g
M-5300 <ω-carboxy-polycaprolactone (n≅2) monoacrylate> [manufactured by Toagosei Co., Ltd., monomer] 2.56 g
2,2′-Azobis(methyl 2-methylpropionate) [initiator] 0.096 g
Propylene glycol monomethyl ether acetate [solvent] 14.9 g

The monomer solution for dropwise addition obtained by mixing the components shown in the composition 1 was added dropwise to 5.0 g of propylene glycol monomethyl ether acetate which had been heated to 80° C., for 3 hours in a nitrogen atmosphere.

Thereafter, 0.096 g of 2,2′-azobis(methyl 2-methylpropionate) was added to the reaction liquid, and the reaction liquid was warmed to 90° C. and then heated for 2 hours. Then, the component concentration of the obtained reaction was adjusted to obtain a fluorine-containing resin 1a shown below, as a 30%-by-mass solution.

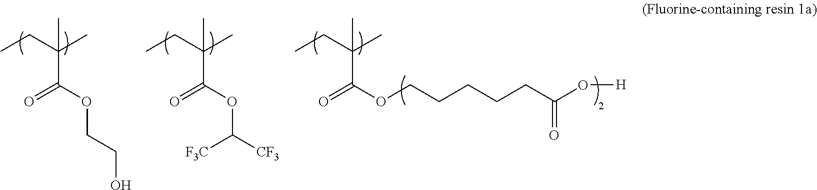

(Step 2: Synthesis of Fluorine-Containing Resin 1)

A solution of the fluorine-containing resin 1a obtained in the step 1, 0.014 g of dibutylhydroxytoluene, and 0.290 g of dioctoate dioctyltin (IV) were mixed, and the mixed liquid was stirred at an internal temperature of 50° C. Further, after the completion of the dropwise addition of 0.522 g of methacryloyloxyethyl isocyanate (“KARENZ MOI”, manufactured by Showa Denko K.K.) for 1 hour, the mixed liquid was stirred for 1 hour. It was confirmed by nuclear magnetic resonance (NMR) that methacryloyloxyethyl isocyanate disappeared, thereby obtaining the fluorine-containing resin 1 shown below.

In addition, the content of the respective repeating units of the fluorine-containing resin 1 was 37/6/57, on a molar basis, from the left repeating unit in the following structural formulae.

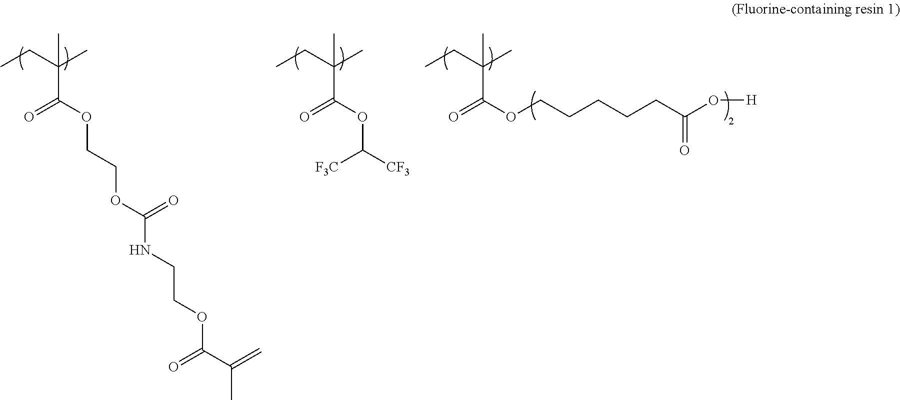

### Example 1: Preparation of Curable Composition 1

The following components were mixed to obtain a curable composition 1.

Furthermore, the amount of the ethylenically unsaturated group in the curable compound was 3.2 mol/g.

In addition, MEGAFACE RS-72-K which will be described later has a repeating unit (repeating unit represented by Formula (A1)) similar to the repeating unit A represented by Structural Formula (I), and a repeating unit (repeating unit represented by Formula (A2)) similar to the repeating unit B represented by General Formula (II), described in claim 10 of JP2010-164965A, as described above.

TB dispersion liquid 1 63.9 parts by mass

Alkali-soluble resin: Specific resin 2 (a solid content of 30%, solvent: propylene glycol monomethyl ether acetate) 10.24 parts by mass

Polymerization initiator: Irgacure OXE02 (manufactured by BASF Japan) 1.81 parts by mass

Polymerizable compound: KAYARAD DPHA (trade name, manufactured by Nippon Kayaku Co., Ltd.) 6.29 parts by mass

Surfactant: MEGAFACE F781F manufactured by DIC Corporation (manufactured by DIC Corporation, a fluorine-containing polymer-type surfactant) 0.02 parts by mass

Solvent: Cyclohexanone 4.66 parts by mass

Curable compound: MEGAFACE RS-72-K (manufactured by DIC Corporation, a solid content of 30%, solvent: propylene glycol monomethyl ether acetate) 10.65 parts by mass

Silane coupling agent: Compound 1 below 0.36 parts by mass

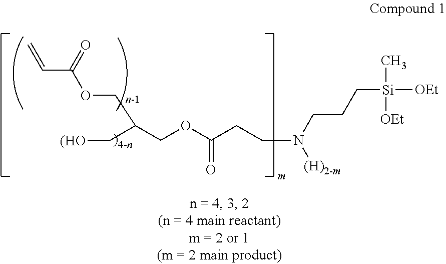

### Example 2: Preparation of Curable Composition 2

The following components were mixed to obtain a curable composition 2.

TB dispersion liquid 1 63.9 parts by mass

Alkali-soluble resin: Specific resin 2 (a solid content of 30%, solvent: propylene glycol monomethyl ether acetate) 10.24 parts by mass

Polymerization initiator: Irgacure OXE02 (manufactured by BASF Japan) 1.81 parts by mass

Polymerizable compound: KAYARAD DPHA (trade name, manufactured by Nippon Kayaku Co., Ltd.) 6.94 parts by mass

Surfactant: MEGAFACE F781F manufactured by DIC Corporation (manufactured by DIC Corporation, fluorine-containing polymer-type surfactant) 0.02 parts by mass

Solvent: Cyclohexanone 4.66 parts by mass

Curable compound: MEGAFACE RS-72-K (manufactured by DIC Corporation, a solid content of 30%, solvent: propylene glycol monomethyl ether acetate) 10.65 parts by mass

Silane coupling agent: Compound 1 1.08 parts by mass

### Example 3: Preparation of Curable Composition 3

The following components were mixed to obtain a curable composition 3.

TB dispersion liquid 1 69.2 parts by mass

Alkali-soluble resin: ACRYCURE RD-F8 (manufactured by Nippon Shokubai Co., Ltd., a solid content of 40%, solvent: propylene glycol monomethyl ether acetate) 2.354 parts by mass

Polymerization initiator: Irgacure OXE02 (manufactured by BASF Japan) 1.41 parts by mass

Polymerizable compound: KAYARAD DPHA (trade name, manufactured by Nippon Kayaku Co., Ltd.) 4.91 parts by mass

Solvent: cyclohexanone 7.93 parts by mass

Curable compound: MEGAFACE RS-72-K (manufactured by DIC Corporation, a solid content of 30%, solvent: propylene glycol monomethyl ether acetate) 10.38 parts by mass

Silane coupling agent: KBM-4803 (manufactured by Shin-Etsu Chemical Co., Ltd.)

1.730 parts by mass

### Example 4: Preparation of Curable Composition 4

The following components were mixed to obtain a curable composition 4.

TB dispersion liquid 1 69.2 parts by mass

Alkali-soluble resin: ACRYCURE RD-F8 (manufactured by Nippon Shokubai Co., Ltd., a solid content of 40%, solvent: propylene glycol monomethyl ether acetate) 4.06 parts by mass

Polymerization initiator: Irgacure OXE02 (manufactured by BASF Japan) 1.57 parts by mass

Polymerizable compound: KAYARAD DPHA (trade name, manufactured by Nippon Kayaku Co., Ltd.) 5.45 parts by mass

Solvent: cyclohexanone 10.14 parts by mass

Curable compound: MEGAFACE RS-72-K (manufactured by DIC Corporation, a solid content of 30%, solvent: propylene glycol monomethyl ether acetate) 5.77 parts by mass

Silane coupling agent: KBM-4803 (manufactured by Shin-Etsu Chemical Co., Ltd.)

1.730 parts by mass

### Example 5: Preparation of Curable Composition 5

The following components were mixed to obtain a curable composition 5.

TB dispersion liquid 1 69.2 parts by mass

Alkali-soluble resin: ACRYCURE RD-F8 (manufactured by Nippon Shokubai Co., Ltd., a solid content of 40%, solvent: propylene glycol monomethyl ether acetate) 4.91 parts by mass

Polymerization initiator: Irgacure OXE02 (manufactured by BASF Japan) 1.65 parts by mass

Polymerizable compound: KAYARAD DPHA (trade name, manufactured by Nippon Kayaku Co., Ltd.) 5.72 parts by mass

Solvent: cyclohexanone 11.24 parts by mass

Curable compound: MEGAFACE RS-72-K (manufactured by DIC Corporation, a solid content of 30%, solvent: propylene glycol monomethyl ether acetate) 3.46 parts by mass

Silane coupling agent: KBM-4803 (manufactured by Shin-Etsu Chemical Co., Ltd.)

1.730 parts by mass

### Example 6: Preparation of Curable Composition 6

The following components were mixed to obtain a curable composition 6.

TB dispersion liquid 1 69.2 parts by mass

Alkali-soluble resin: ACRYCURE RD-F8 (manufactured by Nippon Shokubai Co., Ltd., a solid content of 40%, solvent: propylene glycol monomethyl ether acetate) 5.76 parts by mass

Polymerization initiator: Irgacure OXE02 (manufactured by BASF Japan) 1.73 parts by mass

Polymerizable compound: KAYARAD DPHA (trade name, manufactured by Nippon Kayaku Co., Ltd.) 6.00 parts by mass

Solvent: cyclohexanone 12.4 parts by mass

Curable compound: MEGAFACE RS-72-K (manufactured by DIC Corporation, a solid content of 30%, solvent: propylene glycol monomethyl ether acetate) 1.15 parts by mass

Silane coupling agent: KBM-4803 (manufactured by Shin-Etsu Chemical Co., Ltd.)

1.73 parts by mass

### Example 7: Preparation of Curable Composition 7

The following components were mixed to obtain a curable composition 7.

TB dispersion liquid 1 63.9 parts by mass

Alkali-soluble resin: Specific resin 2 (a solid content of 30%, solvent: propylene glycol monomethyl ether acetate) 10.24 parts by mass

Polymerization initiator: Irgacure OXE02 (manufactured by BASF Japan) 1.81 parts by mass

Polymerizable compound: KAYARAD DPHA (trade name, manufactured by Nippon Kayaku Co., Ltd.) 6.94 parts by mass

Surfactant: MEGAFACE F781F (manufactured by DIC Corporation, fluorine-containing polymer-type surfactant) 0.02 parts by mass

Solvent: cyclohexanone 12.11 parts by mass

Curable compound: fluorine-containing resin 1 3.20 parts by mass

Silane coupling agent: Compound 1 1.08 parts by mass

### Example 8: Preparation of Curable Composition 8

The following components were mixed to obtain a curable composition 8.

TB dispersion liquid 1 69.2 parts by mass

Alkali-soluble resin: ACRYCURE RD-F8 (manufactured by Nippon Shokubai Co., Ltd., a solid content of 40%, solvent: propylene glycol monomethyl ether acetate) 4.06 parts by mass

Polymerization initiator: Irgacure OXE02 (manufactured by BASF Japan) 1.57 parts by mass

Polymerizable compound: KAYARAD DPHA (trade name, manufactured by Nippon Kayaku Co., Ltd.) 5.45 parts by mass

Solvent: cyclohexanone 16.34 parts by mass

Curable compound: fluorine-containing resin 1 1.73 parts by mass

Silane coupling agent: KBM-4803 (manufactured by Shin-Etsu Chemical Co., Ltd.)

1.73 parts by mass

[Example 9: Preparation of Curable Composition 9]

The following components were mixed to obtain a curable composition 9.

TB dispersion liquid 1 69.2 parts by mass

Alkali-soluble resin: ACRYCURE RD-F8 (manufactured by Nippon Shokubai Co., Ltd., a solid content of 40%, solvent: propylene glycol monomethyl ether acetate) 4.06 parts by mass

Polymerization initiator: Irgacure OXE02 (manufactured by BASF Japan) 1.57 parts by mass

Polymerizable compound: KAYARAD DPHA (trade name, manufactured by Nippon Kayaku Co., Ltd.) 5.45 parts by mass

Solvent: cyclohexanone 11.59 parts by mass

Curable compound: MEGAFACE RS-55 (manufactured by DIC Corporation, a solid content of 40%, solvent: methyl isobutyl ketone) 4.32 parts by mass

Silane coupling agent: KBM-4803 (manufactured by Shin-Etsu Chemical Co., Ltd.)

1.730 parts by mass

### Example 10: Preparation of Curable Composition 10

The following components were mixed to obtain a curable composition 10.

TB dispersion liquid 1 69.2 parts by mass

Alkali-soluble resin: ACRYCURE RD-F8 (manufactured by Nippon Shokubai Co., Ltd., a solid content of 40%, solvent: propylene glycol monomethyl ether acetate) 4.06 parts by mass

Polymerization initiator: Irgacure OXE02 (manufactured by BASF Japan) 1.57 parts by mass

Polymerizable compound: KAYARAD DPHA (trade name, manufactured by Nippon Kayaku Co., Ltd.) 5.45 parts by mass

Solvent: cyclohexanone 11.59 parts by mass

Curable compound: MEGAFACE RS-56 (manufactured by DIC Corporation, a solid content of 40%, solvent: methyl isobutyl ketone) 4.32 parts by mass

Silane coupling agent: KBM-4803 (manufactured by Shin-Etsu Chemical Co., Ltd.)

1.730 parts by mass

### Comparative Example 1: Preparation of Curable Composition 11

The following components were mixed to obtain a curable composition 11.

TB dispersion liquid 1 69.2 parts by mass

Alkali-soluble resin: ACRYCURE RD-F8 (manufactured by Nippon Shokubai Co., Ltd., a solid content of 40%, solvent: propylene glycol monomethyl ether) 6.19 parts by mass

Polymerization initiator: Irgacure OXE02 (manufactured by BASF Japan) 1.78 parts by mass

Polymerizable compound: KAYARAD DPHA (trade name, manufactured by Nippon Kayaku Co., Ltd.) 6.13 parts by mass

Silane coupling agent: KBM-4803 (manufactured by Shin-Etsu Chemical Co., Ltd.)

1.730 parts by mass

Solvent: cyclohexanone 12.9 parts by mass

### Comparative Example 2: Preparation of Curable Composition 12

The following components were mixed to obtain a curable composition 12.

TB dispersion liquid 1 69.2 parts by mass

Alkali-soluble resin: ACRYCURE RD-F8 (manufactured by Nippon Shokubai Co., Ltd., a solid content of 40%, solvent: propylene glycol monomethyl ether acetate) 2.354 parts by mass

Polymerization initiator: Irgacure OXE02 (manufactured by BASF Japan) 1.41 parts by mass

Polymerizable compound: KAYARAD DPHA (trade name, manufactured by Nippon Kayaku Co., Ltd.) 4.91 parts by mass

Silane coupling agent: KBM-4803 (manufactured by Shin-Etsu Chemical Co., Ltd.)

1.730 parts by mass

Compound 2 below: 3.11 parts by mass

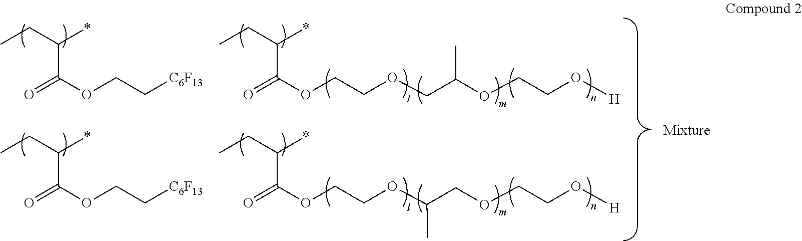

### Comparative Example 3: Preparation of Curable Composition 13

The following components were mixed to obtain a curable composition 13.

TB dispersion liquid 1 69.2 parts by mass

Alkali-soluble resin: ACRYCURE RD-F8 (manufactured by Nippon Shokubai Co., Ltd., a solid content of 40%, solvent: propylene glycol monomethyl ether) 4.48 parts by mass

Polymerization initiator: Irgacure OXE02 (manufactured by BASF Japan) 1.61 parts by mass

Polymerizable compound: KAYARAD DPHA (trade name, manufactured by Nippon Kayaku Co., Ltd.) 5.59 parts by mass

Curable compound: MEGAFACE RS-72-K (manufactured by DIC Corporation, a solid content of 30%, solvent: propylene glycol monomethyl ether acetate) 10.38 parts by mass

Solvent: cyclohexanone 6.65 parts by mass

### Comparative Example 4

The black radiation-sensitive composition A described in paragraph 0200 of JP2012-169556A mentioned above was manufactured, and subjected to various evaluations which will be described later. Further, the black radiation-sensitive composition A did not include a curable compound and a silane coupling agent.

<Manufacture of Light-Shielding Film>

Any one of the curable compositions 1 to 10, and 11 to 13 manufactured above was applied onto an 8-inch glass substrate Eagle XG (manufactured by Corning Inc.) by a spin coating method, and then a heating treatment (prebaking) was carried out for 120 seconds, using a hot plate at 80° C., thereby forming a composition layer on the glass substrate. Next, the composition layer obtained above was exposed using an i-ray stepper exposure device FPA-3000i5+(manufactured by CANON Inc.), the wafer was exposed through a linear 300-μm mask (a width of 300 μm and a length of 4 mm), at an exposure dose of 200 mJ/cm². Subsequently, the exposed composition layer was subjected to a puddle development (development time: 40 seconds) with 0.01% by mass of tetramethylammonium hydroxide (TMAH), using AD-1200 (manufactured by MIKASA). In addition, the composition layer which had been subjected to the developing treatment was subjected to a heating treatment (post-baking) at 150° C. for 1 hour, using a clean oven CLH-21CDH (manufactured by Koyo Thermo Systems Co., Ltd.), thereby forming a light-shielding film having a film thickness of 2 to 2.5 μm.

<Evaluation of Optical Density (OD)>

Light at 400 to 700 nm was incident on the manufactured light-shielding film, and the transmittance was measured using a spectrometer UV4100 (trade name) manufactured by HITACHI High-Technologies Corporation.

<Evaluation of Reflectivity>

Light at 400 to 700 nm was incident onto the manufactured light-shielding film at an angle of incidence of 5°, and the reflectivity was measured using a spectrometer UV4100 (trade name) manufactured by HITACHI High-Technologies Corporation.

<Evaluation of Chipping of Light-Shielding Film: Evaluation of Tape Pull>

CT-18 (manufactured by Nichiban Co., Ltd.) was strongly pressed on the manufactured linear 300-μm (a width of 300 μm and a length of 4 mm) light-shielding film, and peeled by once drawing the edge of the tape at a 45-degree edge. Using an optical microscope MT-3600LW (manufactured by FLOVEL Corporation), the state of the light-shielding film after the tape peeling (tape pull) was compared with the state of the light-shielding film before the tape pull, and evaluated in accordance with the evaluation standard as shown below. “2” or more was defined as being acceptable.

“3”: The destruction of the pattern edge of the 300-μm linear light-shielding film was not observed on the glass substrate, which was evaluated as a permissible level.

“2”: The destruction of the pattern edge of the 300-μm linear light-shielding film was observed on 1 or more and 5 or less positions on the glass substrate, which was evaluated as a permissible level.

“1”:”: The destruction of the pattern edge of the 300-μm linear light-shielding film was observed on 6 or more positions on the glass substrate, which was evaluated as a non-permissible level.

<Evaluation of Linearity>

Using an optical microscope MT-3600LW (manufactured by FLOVEL Corporation), the line width was measured at 255 points on the manufactured linear 300-μm light-shielding film, and the 3σ of the line width was calculated and evaluated in accordance with the evaluation standard as shown below. Further, “2” or more is defined as an acceptable range.

“3”: The 3σ of the linear 300-μm line width was less than 1 μm.

“2”: The 3σ of the linear 300-μm line width was 1 μm or more and less than 5 μm.

“1”: The 3σ of the linear 300-μm line width was 5 μm or more.

Moreover, “Film thickness of light-shielding film” in Table 1 below represents an average film thickness. The method for measuring the average film thickness is as described above.

In addition, “Concentration (% by mass) of black pigment”, “Amount (% by mass)” in the section of “Curable compound”, and “Amount (% by mass)” in the section of “Silane coupling agent” all represent % by mass of the respective components with respect to the total solid content in the composition.

TABLE 1

| | Concen- | | | | | Film | | | | |
|---|---|---|---|---|---|---|---|---|---|---|
| | tration | Curable compound | | Silane coupling agent | | thickness | | | | |
| | (% by | | Amount | | Amount | (μm) of | | | | |
| | mass) | | (% | | (% | Light- | Evaluation | | | |
| | of black | | by | | by | shielding | | Reflectivity | Line- | Chip- |
| Table 1 | pigment | Type | mass) | Type | mass) | film | OD | (%) | arity | ping |
| Example 1 | 45 | MEGAFACE RS-72-K | 9 | Compound 1 | 1 | 2.2 | 3 | 1.9 | 3 | 3 |
| Example 2 | 45 | MEGAFACE RS-72-K | 9 | Compound 1 | 3 | 2.2 | 3 | 2 | 3 | 3 |
| Example 3 | 50 | MEGAFACE RS-72-K | 9 | KBM-4803 | 5 | 2 | 3 | 2 | 3 | 3 |
| Example 4 | 50 | MEGAFACE RS-72-K | 5 | KBM-4803 | 5 | 2 | 3 | 2.6 | 3 | 3 |
| Example 5 | 50 | MEGAFACE RS-72-K | 3 | KBM-4803 | 5 | 2 | 3 | 3.9 | 3 | 3 |
| Example 6 | 50 | MEGAFACE RS-72-K | 1 | KBM-4803 | 5 | 2 | 3 | 4 | 3 | 2 |
| Example 7 | 45 | Fluorine-containing resin 1 | 9 | Compound 1 | 3 | 2 | 3 | 1.4 | 3 | 3 |
| Example 8 | 50 | Fluorine-containing resin 1 | 5 | KBM-4803 | 5 | 2 | 3 | 1.5 | 3 | 3 |
| Example 9 | 50 | MEGAFACE RS-55 | 5 | KBM-4803 | 5 | 2 | 3 | 2 | 2 | 3 |
| Example 10 | 50 | MEGAFACE RS-56 | 5 | KBM-4803 | 5 | 2 | 3 | 1.6 | 2 | 3 |
| Comparative | 50 | — | 0 | KBM-4803 | 5 | 2 | 3 | 5.1 | 3 | 1 |
| Example 1 | | | | | | | | | | |
| Comparative | 50 | -(Compound 2) | 9 | KBM-4803 | 5 | 2 | 3 | 4 | 1 | 2 |
| Example 2 | | | | | | | | | | |
| Comparative | 50 | MEGAFACE RS-72-K | 9 | — | 0 | 2 | 3 | 2 | 3 | 1 |
| Example 3 | | | | | | | | | | |

| | | | | | | |
|---|---|---|---|---|---|---|
| Comparative | Black radiation-sensitive composition A in JP2012-169556A | 2 | 3 | 5.1 | 3 | 1 |
| Example 4 | | | | | | |

As shown in Table 1, the light-shielding film formed of the curable composition including predetermined components had excellent characteristics. Among those, it was confirmed that as the content of the curable compound increases, various effects become more excellent.

On the other hand, in Comparative Examples 1 and 2 in which the curable compound was not used, and Comparative Example 3 in which the silane coupling agent was not used, desired effects were not obtained.

In the same manner except that the titanium black of Example 3 was changed to carbon black (trade name, “Color Black S170”, manufactured by Degussa Co., Ltd., an average primary particle diameter of 17 nm, a BET specific surface area of 200 m²/g, carbon black produced by a gas black system), a curable composition 3-A was obtained. The same evaluation as in Example 3 was performed, and thus, it could be seen that the results were equivalent to Example 3 except that the chipping corresponded to “2”.

In the same manner except that the polymerization initiator of Example 3 was changed to IRGACURE-907 (manufactured by BASF Japan), a curable composition 3-B was obtained (referred to as Example 3-B). Using this curable composition, the same evaluation as in Example 3 was performed, and thus, it could be seen that the results were equivalent to Example 3 except that the chipping corresponded to “2”.

In the same manner except that the polymerization initiator of Example 3 was changed to Irgacure OXE03 (manufactured by BASF Japan), a curable composition 3-C was obtained (referred to as Example 3-C). Using this curable composition, the same evaluation as in Example 3 was performed, and thus, it could be seen that the results were equivalent to Example 3. Further, the same evaluation was performed with increasing each film thickness by 1.3 times, and thus, it could be seen that Example 3-C is more excellent than Example 3 in terms of the linearity and the chipping.

In the same manner except that the polymerization compound of Example 3 was changed to KAYARAD DPHA (2.91 parts by mass) and PET-30 (pentaerythritol triacrylate, manufactured by Nippon Kayaku Co., Ltd.) (2.0 parts by mass), a curable composition 3-D was obtained. The same evaluation as in Example 3 was performed, and thus, it could be seen that the results were equivalent to Example 3.

(Preparation of Black Pigment Dispersion Liquid CB)

The following components were mixed to obtain a mixed liquid, and the obtained mixed liquid was subjected to a dispersion treatment by means of beads mills, thereby obtaining a black pigment dispersion liquid CB.

<Composition>
Pigment (trade name, “Color Black S170”, manufactured by Degussa Co., Ltd., carbon black produced by a gas black system, having an average primary particle diameter of 17 nm and a BET specific surface area of 200 m²/g) 25.0 parts by mass
Dispersant: trade name “Disperbyk111” (manufactured by BYK Japan KK) 11.3 parts by mass
Propylene glycol monomethyl ether acetate 31.9 parts by mass
Butyl acetate 31.9 parts by mass

The above components were weighed, mixed, and stirred to obtain a mixed liquid.

The obtained mixed liquid was subjected to a dispersion treatment under the following dispersion conditions, using Whole length-Sepa APEX MILL manufactured by Kotobuki Industries Co., Ltd.

<Dispersion Conditions>
Bead diameter: φ0.03 mm
Bead species: Zirconia beads (YTZ balls, manufactured by Nikkato Corp.)
Beads filling rate: 40% by volume
Circumferential speed of mill: 4 m/sec
Amount of mixed liquid to be subjected to a dispersion treatment: 500 g
Circulation flow rate (pump supply amount): 2 kg/hour
Temperature of treatment liquid: 15° C. to 20° C.
Cooling water: tap water

In the same manner except that the TB dispersion liquid 1 of Example 3 was changed to the black pigment dispersion liquid CB, a curable composition 3-E was obtained. The same evaluation as in Example 3 was performed, and thus, it could be seen that the results were equivalent to Example 3 except that the chipping and the linearity corresponded to “2”.

In the same manner except that the pigment was changed to Pigment Red 254 (manufactured by Ciba Specialty Chemicals Inc., trade name: BK-CF) in preparation of the black pigment dispersion liquid CB, a pigment dispersion liquid R was obtained.

In the same manner except that 62.0 parts by mass of the TB dispersion liquid 1 and 7.2 parts by mass of the pigment dispersion liquid R were used instead of the TB dispersion liquid 1 of Example 3, a curable composition 3-F was obtained. The same evaluation as in Example 3 was performed, and thus, it could be seen that the results were equivalent to Example 3, but the light-shielding properties were excellent.

### EXPLANATION OF REFERENCES

2, 20, 30, 40 Solid-state imaging devices
3 CMOS sensor
4 Circuit board
5 Ceramic substrate
5a Opening
6 IR cut filter
7 Taking lens
8 Lens holder
9 Holding barrel
10, 11, 21, 31, 41 Light-shielding films (light-shielding layers
12 Black layer
14 Coating layer
100 Substrate

What is claimed is:

1. A curable composition comprising:
a curable compound having at least one selected from the group consisting of a fluorine atom, a silicon atom, a linear alkyl group having 8 or more carbon atoms, and a branched alkyl group having 3 or more carbon atoms, and a curable functional group;
a silane coupling agent; and
a black pigment.

2. The curable composition according to claim 1, wherein the silane coupling agent is a silane coupling agent with a molecular weight of 270 or more, having at least one curable functional group selected from the group consisting of a (meth)acryloyloxy group, an epoxy group, and an oxetanyl group.

3. The curable composition according to claim 1, wherein the curable compound has at least one curable functional group selected from the group consisting of a (meth)acryloyloxy group, an epoxy group, an oxetanyl group, an isocyanate group, a hydroxyl group, an amino group, a carboxyl group, a thiol group, an alkoxysilyl group, a methylol group, a vinyl group, a (meth)acrylamide group, a styryl group, and a maleimide group.

4. The curable composition according to claim 1, wherein the curable compound has at least one curable functional group selected from the group consisting of a (meth)acryloyloxy group, an epoxy group, and an oxetanyl group.

5. The curable composition according to claim 1, further comprising:
a polymerizable compound;
a polymerization initiator;
an alkali-soluble resin; and
a solvent.

6. The curable composition according to claim 1, wherein the curable compound alone is capable of forming a film with a refractive index of 1.1 to 1.5 at a wavelength of 550 nm.

7. The curable composition according to claim 1, wherein the content of the silane coupling agent is 0.1% to 10% by mass with respect to the total solid content in the curable composition.

8. The curable composition according to claim 1, wherein the content of the curable compound is 0.1% to 20% by mass with respect to the total solid content in the curable composition.

9. The curable composition according to claim 1, wherein the content of the black pigment is 20% to 80% by mass with respect to the total solid content in the curable composition.

10. The curable composition according to claim 1, wherein the black pigment is titanium black.

11. An infrared cut filter with a light-shielding film, comprising:
an infrared cut filter; and
a light-shielding film formed of the curable composition according to claim 1, disposed on at least a part of the surface of the infrared cut filter.

12. A solid-state imaging device comprising the infrared cut filter according to claim 11.

13. The curable composition according to claim 2, wherein the curable compound has at least one curable functional group selected from the group consisting of a (meth)acryloyloxy group, an epoxy group, an oxetanyl group, an isocyanate group, a hydroxyl group, an amino group, a carboxyl group, a thiol group, an alkoxysilyl group, a methylol group, a vinyl group, a (meth)acrylamide group, a styryl group, and a maleimide group.

14. The curable composition according to claim 2, wherein the curable compound has at least one curable functional group selected from the group consisting of a (meth)acryloyloxy group, an epoxy group, and an oxetanyl group.

15. The curable composition according to claim 3, wherein the curable compound has at least one curable functional group selected from the group consisting of a (meth)acryloyloxy group, an epoxy group, and an oxetanyl group.

16. The curable composition according to claim 2, further comprising:
a polymerizable compound;
a polymerization initiator;
an alkali-soluble resin; and
a solvent.

17. The curable composition according to claim 3, further comprising:
a polymerizable compound;
a polymerization initiator;
an alkali-soluble resin; and
a solvent.

18. The curable composition according to claim 4, further comprising:
a polymerizable compound;
a polymerization initiator;
an alkali-soluble resin; and
a solvent.

19. The curable composition according to claim 2, wherein the curable compound alone is capable of forming a film with a refractive index of 1.1 to 1.5 at a wavelength of 550 nm.

20. The curable composition according to claim 3, wherein the curable compound alone is capable of forming a film with a refractive index of 1.1 to 1.5 at a wavelength of 550 nm.
